(19) United States
(12) Patent Application Publication
(10) Pub. No.: US 2026/0039254 A1
(43) Pub. Date: Feb. 5, 2026

(54) POWER AMPLIFICATION DEVICE

(71) Applicant: Murata Manufacturing Co., Ltd., Kyoto-fu (JP)

(72) Inventors: Kouhei JITOUSHO, Nagaokakyo-shi (JP); Tetsurou ASHIDA, Nagaokakyo-shi (JP); Tomoya ODA, Nagaokakyo-shi (JP); Shohei IMAI, Nagaokakyo-shi (JP)

(73) Assignee: Murata Manufacturing Co., Ltd., Kyoto-fu (JP)

(21) Appl. No.: 19/355,775

(22) Filed: Oct. 10, 2025

Related U.S. Application Data
(63) Continuation of application No. PCT/JP2024/014431, filed on Apr. 9, 2024.

(30) Foreign Application Priority Data
Apr. 12, 2023 (JP) 2023-065255

(51) Int. Cl. H03F 1/02; H03F 3/213; H03F 3/45

(52) U.S. Cl. CPC H03F 1/0288; H03F 3/213; H03F 3/45475; H03F 2200/451

(57) ABSTRACT

A power amplification device includes a substrate having first and second surfaces on sides opposite to each other; a first integrated circuit and a coupler that are on the first surface; and a second integrated circuit on the second surface. The first integrated circuit includes a splitter; a carrier amplifier that amplifies an inputted high-frequency signal; a peak amplifier that amplifies an inputted high-frequency signal; a first bias circuit that provides bias to the carrier amplifier; and a second bias circuit that provides bias to the peak amplifier. The second integrated circuit includes a detector circuit that outputs a control signal to control bias of the peak amplifier, and the detector circuit varies a threshold for the control signal, based on a first high-frequency signal inputted to the first integrated circuit from the outside and a signal indicating a drive level of the carrier amplifier.

### CROSS-REFERENCE TO RELATED APPLICATIONS

This application claims benefit of priority to International Patent Application No. PCT/JP2024/014431, filed Apr. 9, 2024, and to Japanese Patent Application No. 2023-065255, filed Apr. 12, 2023, the entire contents of each are incorporated herein by reference.

### BACKGROUND

### Technical Field

The present disclosure relates to a power amplification device.

### Background Art

A power amplification device includes a power amplifier circuit, and an example of such a highly efficient power amplifier circuit is a Doherty amplifier. Generally, a Doherty amplifier includes a carrier amplifier that operates regardless of the power level of the input signal and a peak amplifier that turns off when the power level of the input signal is low and turns on when the power level is high. The carrier amplifier and the peak amplifier are coupled in parallel. In such a Doherty amplifier, when the power level of a high-frequency input signal is high, the carrier amplifier operates while maintaining saturation at its saturated output power level. As a result, the Doherty amplifier can achieve higher efficiency compared to typical power amplifier circuits.

As discussed below, U.S. Patent Application Publication No. 2016/0241209, U.S. Patent Application Publication No. 2020/0028472 and Japanese Unexamined Patent Application Publication No. 2019-41277 describe techniques to control the bias of the peak amplifier.

The technique described in U.S. Patent Application Publication No. 2016/0241209 detects saturation of the carrier amplifier using the bias circuit for the carrier amplifier and controls the bias circuit for the peak amplifier based on the detection signal.

The technique described in U.S. Patent Application Publication No. 2020/0028472 detects saturation of the carrier amplifier using the output signal of the carrier amplifier and controls the bias circuit for the peak amplifier based on the detection signal.

The technique described in Japanese Unexamined Patent Application Publication No. 2019-41277 controls the bias circuit for the peak amplifier based on the level of the high frequency input signal inputted to the Doherty amplifier or the level of the high frequency input signal inputted to the carrier amplifier.

### SUMMARY

In the techniques described in U.S. Patent Application Publication No. 2016/0241209 and U.S. Patent Application Publication No. 2020/0028472, it takes about several tens of nanoseconds for the circuit that detects saturation of the carrier amplifier to respond. Therefore, the following inconveniences can occur. For example, when a high frequency input signal with instantaneous power increases (much shorter than several tens of nanoseconds) is inputted to the Doherty amplifier, periods during which the carrier amplifier is saturated may occur within several tens of nanoseconds between the time the carrier amplifier starts saturating and the time the bias point of the peak amplifier changes. This can result in degradation in the quality of the high-frequency output signal of the Doherty amplifier. When such a Doherty amplifier is used in a communication device, there is a risk that high communication quality cannot be maintained. The technique described in Japanese Unexamined Patent Application Publication No. 2019-41277 operates based on the high frequency input signal level. However, this technique detects the high frequency input signal level using a bias circuit, and the response speed is basically considered to be slow. This can lead to degradation in the quality of the high-frequency output signal of the Doherty amplifier.

Accordingly, the present disclosure suppresses degradation in the quality of high-frequency output signals.

A power amplification device according to an aspect of the present disclosure includes a substrate including a first surface and a second surface on a side opposite to the first surface; a first integrated circuit and a coupler that are provided on the first surface; and a second integrated circuit provided on the second surface. The first integrated circuit includes: a splitter; a carrier amplifier that amplifies an inputted high-frequency signal; a peak amplifier that amplifies an inputted high-frequency signal; a first bias circuit that provides bias to the carrier amplifier; and a second bias circuit that provides bias to the peak amplifier. The second integrated circuit includes a detector circuit that outputs a control signal to control bias of the peak amplifier. The detector circuit varies a threshold for the control signal, based on a first high-frequency signal inputted to the first integrated circuit from an outside and a signal indicating a drive level of the carrier amplifier.

A power amplification device according to another aspect of the present disclosure includes a substrate including a first surface and a second surface on a side opposite to the first surface; a first integrated circuit and a coupler that are provided on the first surface; and a second integrated circuit provided on the second surface. The first integrated circuit includes: a splitter; a carrier amplifier that amplifies an inputted high-frequency signal; a peak amplifier that amplifies an inputted high-frequency signal; a first bias circuit that provides bias to the carrier amplifier; and a second bias circuit that provides bias to the peak amplifier, the second integrated circuit includes a control circuit. The control circuit includes: a detector circuit that outputs a control signal to control bias of the peak amplifier; and a variable attenuator that receives a first high-frequency signal inputted from an outside to the first integrated circuit and a signal outputted from the first bias circuit and that outputs to the detector circuit, a high-frequency signal obtained by attenuating the first high-frequency signal.

According to the present disclosure, it is possible to suppress degradation in the quality of high-frequency output signals.

### BRIEF DESCRIPTION OF THE DRAWINGS

FIG. 1 illustrates a circuit configuration of a power amplification device of a first embodiment;

FIG. 2 is a schematic diagram illustrating an example of the relationship between high-frequency signal power of a power amplifier circuit of the first embodiment and signals outputted by a detector circuit;

FIG. 3 illustrates a specific example of the detector circuit and a drive-level detector circuit in the power amplifier circuit of the first embodiment.

FIG. 4 illustrates an equivalent circuit of the specific example of the detector circuit and the drive-level detector circuit in the power amplifier circuit of a fifth embodiment.

FIG. 5 illustrates an example of the relationship between high-frequency signal power of the power amplifier circuit of the first embodiment and bias voltage applied to a peak amplifier.

FIG. 6 is a schematic diagram schematically illustrating a cross-sectional structure of the power amplification device of the first embodiment.

FIG. 7 is a plan view of the power amplification device of the first embodiment.

FIG. 8 is a view of a second integrated circuit of the first embodiment when viewed from a substrate.

FIG. 9 is a plan view of a power amplification device of a first modification.

FIG. 10 is a view of a second integrated circuit of the first modification when viewed from a substrate.

FIG. 11 is a plan view of a power amplification device of a second modification.

FIG. 12 is a view of a second integrated circuit of the second modification when viewed from a substrate.

FIG. 13 is a plan view of a power amplification device of a third modification.

FIG. 14 is a view of a second integrated circuit of the third modification when viewed from a substrate.

FIG. 15 is a plan view of a power amplification device of a fourth modification.

FIG. 16 is a view of a second integrated circuit of the fourth modification when viewed from a substrate.

FIG. 17 is a plan view of a power amplification device of a fifth modification.

FIG. 18 is a view of a second integrated circuit of the fifth modification when viewed from a substrate.

FIG. 19 is a plan view of a power amplification device of a sixth modification.

FIG. 20 is a view of a second integrated circuit of the sixth modification when viewed from a substrate.

FIG. 21 is a plan view of a power amplification device of a seventh modification.

FIG. 22 is a view of a second integrated circuit of the seventh modification when viewed from a substrate.

FIG. 23 is a plan view of a power amplification device of an eighth modification.

FIG. 24 is a view of a second integrated circuit of the eighth modification when viewed from a substrate.

FIG. 25 is a plan view of a power amplification device of a ninth modification.

FIG. 26 is a view of a second integrated circuit of the ninth modification when viewed from a substrate.

FIG. 27 is a plan view of a power amplification device of a tenth modification.

FIG. 28 is a view of a second integrated circuit of the tenth modification when viewed from a substrate.

FIG. 29 is a plan view of a power amplification device of an eleventh modification.

FIG. 30 is a view of a second integrated circuit of the eleventh modification when viewed from a substrate.

FIG. 31 is a plan view of a power amplification device of a twelfth modification.

FIG. 32 is a view of a second integrated circuit of the twelfth modification when viewed from a substrate.

FIG. 33 illustrates a configuration of a power amplifier circuit of a second embodiment.

FIG. 34 illustrates a configuration of a detector circuit of the power amplifier circuit of the second embodiment.

FIG. 35 is a plan view of a power amplification device of the second embodiment.

FIG. 36 is a view of a second integrated circuit of the second embodiment when viewed from a substrate.

FIG. 37 illustrates a circuit configuration of a power amplification device according to a third embodiment.

FIG. 38 illustrates a circuit configuration of a peak amplifier according to the third embodiment; and

FIG. 39 illustrates a circuit configuration of a power amplification device according to a fourth embodiment.

### DETAILED DESCRIPTION

Hereinafter, embodiments of a power amplification device of the present disclosure will be described in detail with reference to the drawings. The embodiments are not intended to limit the present disclosure. Each embodiment is illustrative, and it is obvious that configurations illustrated in different embodiments can be partially replaced or combined with each other. In the second and subsequent embodiments, the description of the same matters as the first embodiment will be omitted, and only different points will be described. In particular, similar operational effects resulting from the same configuration will not be described repeatedly for each embodiment.

### First Embodiment

### (Overall Configuration)

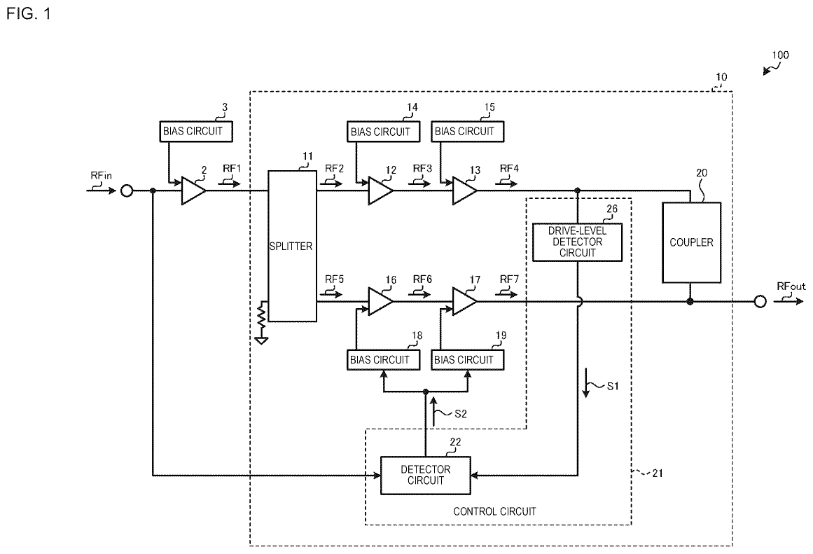

FIG. 1 illustrates a circuit configuration of a power amplification device of a first embodiment. A power amplification device 100 includes a power amplifier circuit 1. The power amplifier circuit 1 includes an amplifier 2, a bias circuit 3, and a Doherty amplifier 10. The Doherty amplifier 10 includes a splitter 11, a first-stage (driver-stage) carrier amplifier 12, a final-stage (power-stage) carrier amplifier 13, a bias circuit 14, a bias circuit 15, a first-stage (driver-stage) peak amplifier 16, a final-stage (power stage) peak amplifier 17, a bias circuit 18, a bias circuit 19, a coupler 20, and a control circuit 21. The control circuit 21 includes a detector circuit 22 and a drive-level detector circuit 26. The Doherty amplifier 10 includes two stages, but the present disclosure is not limited thereto. The number of stages of the Doherty amplifier 10 may be one or three or more. The bias circuits 14 and 15 are examples of a “first bias circuit” of the present disclosure. The bias circuits 18 and 19 are examples of a “second bias circuit” of the present disclosure.

The bias circuit 3 provides bias to the amplifier 2. The amplifier 2 receives a radio-frequency (RF) signal (hereinafter, referred to as a “signal RFin”). The frequency of the signal RFin is, for example, about several gigahertz (GHz), and the signal RFin is referred to as a high-frequency signal RFin hereinafter. The amplifier 2 amplifies the inputted high-frequency signal RFin. The amplifier 2 then outputs the resulting signal as a high-frequency signal RF1 to the splitter 11.

The splitter 11 is a 90-degree hybrid circuit. The 90-degree hybrid circuit splits the high-frequency signal RF1 into high-frequency signals RF2 and RF5, which differ in phase by substantially 90°. The 90-degree hybrid circuit outputs the high-frequency signal RF2 to the carrier amplifier 12 and outputs the high-frequency signal RF5 to the peak amplifier 16. The term “substantially 90°” includes not only a phase difference of 90° but also phase differences ranging from 45° to 135°.

The phase of the high-frequency signal RF5 is exemplified as lagging behind that of the high-frequency signal RF2 by 90°. The power of the high-frequency signal RF5 is exemplified as being equal to that of the high-frequency signal RF2.

The bias circuit 14 provides bias to the carrier amplifier 12. The bias circuit 15 provides bias to the carrier amplifier 13. The carrier amplifier 12 amplifies the high-frequency signal RF2 and outputs the resulting signal as a high-frequency signal RF3 to the carrier amplifier 13. The carrier amplifier 13 amplifies the high-frequency signal RF3 and outputs the resulting signal as a high-frequency signal RF4 to the coupler 20.

The bias circuit 18 provides bias to the peak amplifier 16. The bias circuit 19 provides bias to the peak amplifier 17. The peak amplifier 16 amplifies the high-frequency signal RF5 and outputs the resulting signal as a high-frequency signal RF6 to the peak amplifier 17. The peak amplifier 17 amplifies the high-frequency signal RF6 and outputs as a high-frequency signal RF7 to the coupler 20.

The coupler 20 couples the high-frequency signals RF4 and RF7. In the first embodiment, the coupler 20 is composed of a phase shifter, but the present disclosure is not limited thereto. The coupler 20 outputs the high-frequency signal RF4 with its phase delayed by 90°. The sum of the high-frequency signal RF7 and the output signal of the coupler 20 is a high-frequency signal RFout.

The drive-level detector circuit 26 outputs, to a detector circuit 22, a signal S1, which indicates the drive level (the operation level) of the carrier amplifier 13, based on the high-frequency signal RF4, which is outputted by the carrier amplifier 13.

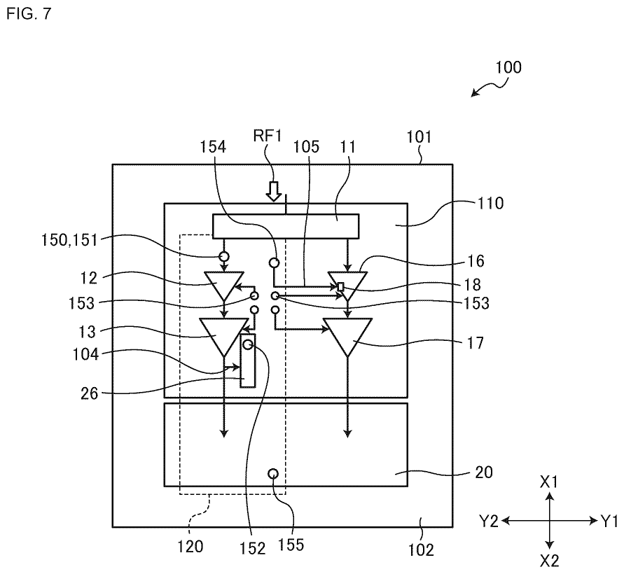

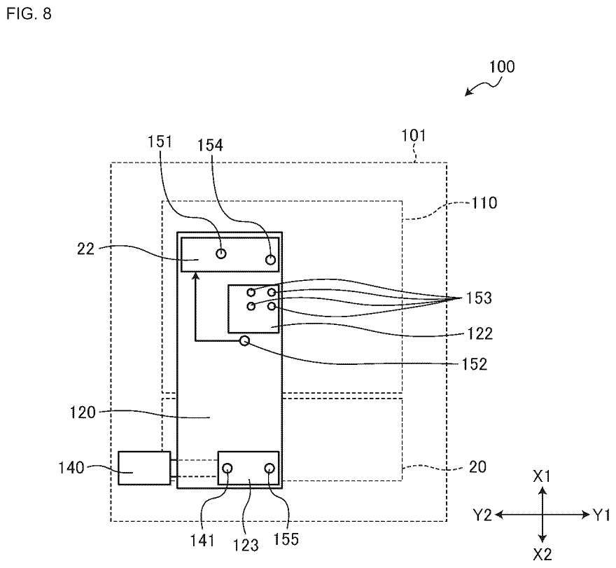

The detector circuit 22 receives the high-frequency signal RFin and the signal S1. In the present disclosure, the detector circuit 22 may receive the high-frequency signal RF1 or RF2 instead of the high-frequency signal RFin. In the later-described layout of the power amplification device 100, an example will be described in which the detector circuit 22 receives the high-frequency signal RF2 (see FIGS. 7 and 8, etc.).

The detector circuit 22 outputs a signal S2 to control the bias circuits 18 and 19 to the bias circuits 18 and 19 based on the high-frequency signal RFin and the signal S1. The bias circuit 18 provides bias to the peak amplifier 16 based on the signal S2. The bias circuit 19 provides bias to the peak amplifier 17 based on the signal S2. That is, the detector circuit 22 controls bias of the peak amplifiers 16 and 17 based on the high-frequency signal RFin and the signal S1.

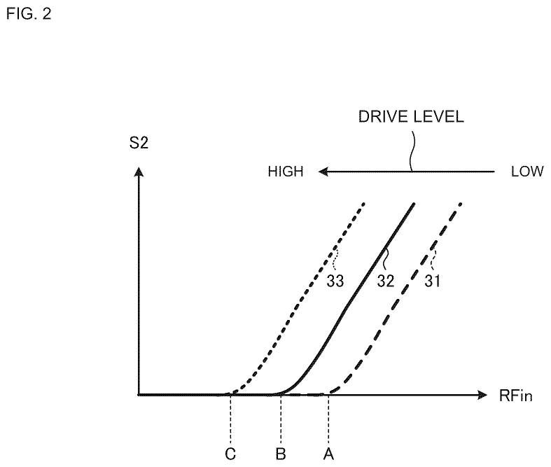

FIG. 2 is a schematic diagram illustrating an example of the relationship between high-frequency signal power of the power amplifier circuit of the first embodiment and the signal outputted by the detector circuit. In FIG. 2, the horizontal axis indicates power of the high-frequency signal RFin, and the vertical axis indicates the signal S2, which is outputted by the detector circuit 22.

The detector circuit 22 varies the rising point of the signal S2 depending on the signal S1. Here, the rising point of the signal S2 can be referred to as a threshold. A waveform 31 represents the relationship between the power of the high-frequency signal RFin and the signal S2 when the drive level of the carrier amplifier 13 is relatively low. A waveform 32 represents the relationship between the power of the high-frequency signal RFin and the signal S2 when the drive level of the carrier amplifier 13 is relatively intermediate. A waveform 33 represents the relationship between the power of the high-frequency signal RFin and the signal S2 when the drive level of the carrier amplifier 13 is relatively high.

In the case where the drive level of the carrier amplifier 13 is relatively low, as represented by the waveform 31, the detector circuit 22 raises the signal S2 when the power of the high-frequency signal RFin reaches a value A. In the range where the power of the high-frequency signal RFin is greater than or equal to the value A, the detector circuit 22 increases the signal S2 as the power of the high-frequency signal RFin increases.

In the case where the drive level of the carrier amplifier 13 is relatively intermediate, as represented by the waveform 32, the detector circuit 22 raises the signal S2 when the power of the high-frequency signal RFin reaches a value B (B<A). In the range where the power of the high-frequency signal RFin is greater than or equal to the value B, the detector circuit 22 increases the signal S2 as the power of the high-frequency signal RFin increases.

In the case where the drive level of the carrier amplifier 13 is relatively high, as represented by the waveform 33, the detector circuit 22 raises the signal S2 when the power of the high-frequency signal RFin reaches a value C (C<B). In the range where the power of the high-frequency signal RFin is greater than or equal to the value C, the detector circuit 22 increases the signal S2 as the power of the high-frequency signal RFin increases.

When the inputted high-frequency signal RFin has high power, which is a main cause of saturation of the carrier amplifiers 12 and 13, the detector circuit 22 outputs the signal S2 to the bias circuits 18 and 19 and allows the bias circuits 18 and 19 to activate the peak amplifiers 16 and 17. Thus, the carrier amplifiers 12 and 13 remain essentially unsaturated.

Here, the response speed of the detector circuit 22 is important. The detector circuit 22, which detects the high-frequency signal RFin, can respond much faster than in the case where saturation of the carrier amplifier is detected using the techniques described in U.S. Patent Application Publication No. 2016/0241209 and U.S. Patent Application Publication No. 2020/0028472. As a result, even if the power of the high-frequency signal RFin increases rapidly, the detector circuit 22 immediately responds and allows the bias circuits 18 and 19 to activate the peak amplifiers 16 and 17, so that the carrier amplifiers 12 and 13 are not saturated even momentarily.

When the temperature or other peripheral environments have changed (for example, the gains of the carrier amplifiers 12 and 13 have increased due to an extremely low temperature), the carrier amplifiers 12 and 13 can be saturated even if the power of the high-frequency signal RFin is low. To accommodate such cases as well, the detector circuit 22 detects the signal S1, which indicates the drive level of the carrier amplifiers 12 and 13, and when the carrier amplifiers 12 and 13 are close to saturation, immediately activates the peak amplifiers 16 and 17 even if the power of the high-frequency signal RFin is low.

Since the detector circuit 22 detects the high-frequency signal RFin, the detector circuit 22 can allow the bias circuits 18 and 19 to activate the peak amplifiers 16 and 17 without causing saturation of the carrier amplifiers 12 and 13 even if it takes time to detect the drive levels of the carrier amplifiers 12 and 13. As a result, the Doherty amplifier 10 can suppress degradation in the quality of the high-frequency signal RFout.

The detector circuit 22 can be regarded as operating in a feedforward manner in response to the high-frequency signal RFin, and in a feedback manner in response to the signal S1. In the first embodiment, the signal S2 to control the bias circuits 18 and 19 is outputted to the bias circuits 18 and 19. However, in the present disclosure, the signal S2 may be outputted to only one of the bias circuits 18 and 19, for example, to only the bias circuit 18. In the later-described layout of the power amplification device 100, an example will be described in which the signal S2 is outputted only to the bias circuit 18 (see FIGS. 7 and 8, etc.).

### (Specific Example of Detector Circuit and Drive-level Detector Circuit)

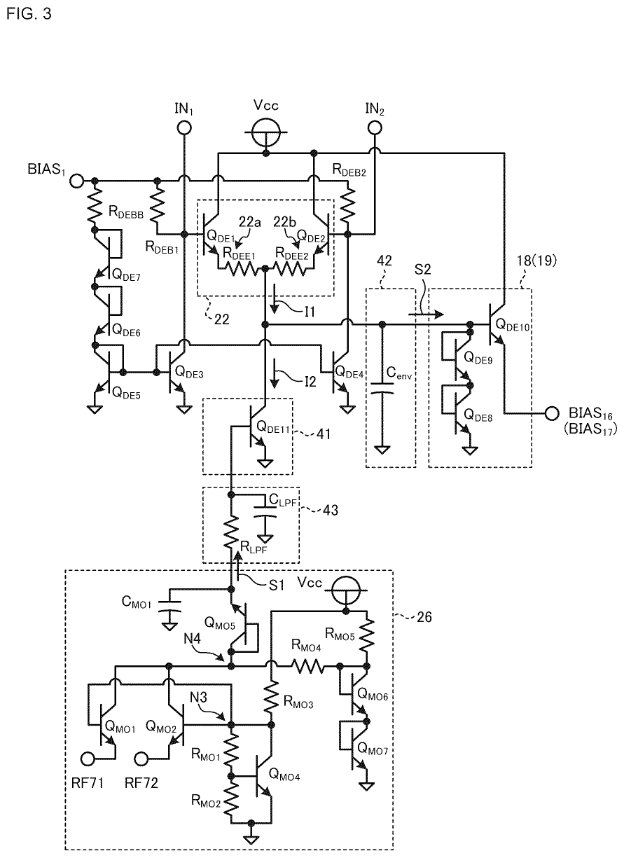

FIG. 3 illustrates a specific example of the detector circuit and the drive-level detector circuit in the power amplifier circuit of the first embodiment. FIG. 3 also illustrates a circuit element to provide bias to the detector circuit 22. A low pass filter 42, the bias circuit 18, and the bias circuit 19 illustrated in FIG. 3 may be omitted. The low pass filter 42 can be omitted, for example, when a good differential signal is obtained. The bias circuit 18 and the bias circuit 19 can be omitted, for example, when the transistors (amplifying transistors) to be biased are small.

The detector circuit 22 includes transistors Q_{DE1} and Q_{DE2} and resistors R_{DEE1} and R_{DEE2}.

In the present disclosure, each transistor is a bipolar transistor. However, the present disclosure is not limited thereto. The bipolar transistors are exemplified as heterojunction bipolar transistors (HBTs), but the present disclosure is not limited thereto. The transistors may be, for example, field-effect transistors (FETs). The transistors may be multi-finger transistors, in which a plurality of unit transistors are electrically coupled in parallel. Each unit transistor refers to the minimum structure that constitutes a transistor.

The collector of the transistor Q_{DE1} is electrically coupled to a power supply potential Vcc. The emitter of the transistor Q_{DE1} is electrically coupled to one end of the resistor R_{DEE1}. That is, the transistor Q_{DE1} and the resistor R_{DEE1} are coupled as an emitter-follower. The transistor Q_{DE1} and the resistor R_{DEE1} constitute a first emitter-follower circuit 22a.

The detector circuit 22 may include a source-follower circuit instead of the first emitter-follower circuit 22a.

The collector of the transistor Q_{DE2} is electrically coupled to the power supply potential Vcc. The emitter of the transistor Q_{DE2} is electrically coupled to one end of the resistor R_{DEE2}. That is, the transistor Q_{DE2} and the resistor R_{DEE2} are coupled as an emitter-follower. The transistor Q_{DE2} and the resistor R_{DEE2} constitute a second emitter-follower circuit 22b.

The detector circuit 22 may include a source-follower circuit instead of the second emitter-follower circuit 22b.

The other end of the resistor R_{DEE1} and the other end of the resistor R_{DEE2} are electrically coupled. The sum of the output current of the first emitter-follower circuit 22a and the output current of the second emitter-follower circuit 22b is an output current I1 of the detector circuit 22.

Resistors R_{DEBB}, R_{DEB1}, and R_{DEB2} and transistors Q_{DE5}, Q_{DE6}, and Q_{DE7} apply bias voltage to the bases of the transistors Q_{DE1} and Q_{DE2}.

One end of the resistor R_{DEBB}, one end of the resistor R_{DEB1}, and one end of the resistor R_{DEB2} are electrically coupled.

The other end of the resistor R_{DEBB} is electrically coupled to the collector and base of the transistor Q_{DE7}. That is, the transistor Q_{DE7} is diode-coupled. The emitter of the transistor Q_{DE7} is electrically coupled to the collector and base of the transistor Q_{DE6}. That is, the transistor Q_{DE6} is diode-coupled. The emitter of the transistor Q_{DE6} is electrically coupled to the collector and base of the transistor Q_{DE5}. That is, the transistor Q_{DE5} is diode-coupled. The emitter of the transistor Q_{DE5} is electrically coupled to a reference potential. The reference potential is exemplified as ground potential, but the present disclosure is not limited thereto.

The one end of the resistor R_{DEBB}, the one end of the resistor R_{DEB1}, and the one end of the resistor R_{DEB2} receive a bias current BIAS₁. The resistor R_{DEBB} and the transistors Q_{DE7}, Q_{DE6}, and Q_{DE5} generate a constant voltage. This voltage is applied to the base of the transistor Q_{DE1} via the resistor R_{DEB1} and to the base of the transistor Q_{DE2} via the resistor R_{DEB2}.

Each of transistors Q_{DE3} and Q_{DE4} is coupled to the transistor Q_{DE5} as a current mirror. The collector of the transistor Q_{DE3} is electrically coupled to the base of the transistor Q_{DE1}. The transistor Q_{DE3} is thereby able to adjust the base current of the transistor Q_{DE1}. The collector of the transistor Q_{DE4} is electrically coupled to the base of the transistor Q_{DE2}. The transistor Q_{DE4} is thereby able to adjust the base current of the transistor Q_{DE2}.

The bases of the transistors Q_{DE1} and Q_{DE2}, respectively, receive high-frequency signals IN₁ and IN₂, which are obtained by transforming the high-frequency signal RFin into a differential signal. The high-frequency signals IN₁ and IN₂ can be obtained by, for example, inputting the high-frequency signal RFin to a balun.

The other end of the resistor R_{DEE1} and the other end of the resistor R_{DEE2} are electrically coupled to a constant-current circuit 41. The constant-current circuit 41 includes a transistor Q_{DE11}. The constant-current circuit 41 serves as a current bias circuit for the detector circuit 22.

The drive-level detector circuit 26 includes resistors R_{MO1}, R_{MO2}, R_{MO3}, R_{MO4}, and R_{MO5}, transistors Q_{MO1}, Q_{MO2}, Q_{MO4}, Q_{MO5}, Q_{MO6}, and Q_{MO7}, and a capacitor C_{MO1}.

In this description, the carrier amplifier 13 (see FIG. 1) is assumed to be a pair of differential amplifiers (differential amplifier) and output high-frequency signals RF71 and RF72, which constitute a pair of differential signals.

The emitter of the transistor Q_{MO1} receives the high-frequency signal RF71. The emitter of the transistor Q_{MO1} is exemplified as being electrically coupled to an output terminal (the collector or drain of the output transistor) of one of the amplifiers in the carrier amplifier 13.

The emitter of the transistor Q_{MO2} receives the high-frequency signal RF72. The emitter of the transistor Q_{MO2} is exemplified as being electrically coupled to an output terminal (the collector or drain of the output transistor) of the other amplifier in the carrier amplifier 13.

The bases of the transistors Q_{MO1} and Q_{MO2} are electrically coupled to a node N3. The collectors of the transistors Q_{MO1} and Q_{MO2} are electrically coupled to a node N4.

The resistors R_{MO1}, R_{MO2}, and R_{MO3} and the transistor Q_{MO4} apply voltage to the node N3. That is, the resistors R_{MO1}, R_{MO2}, and R_{MO3} and the transistor Q_{MO4} provide bias to the bases of the transistors Q_{MO1} and Q_{MO2}.

One end of the resistor R_{MO3} is electrically coupled to the power supply potential Vcc. The other end of the resistor R_{MO3} is electrically coupled to the node N3, the collector of the transistor Q_{MO4}, and one end of the resistor R_{MO1}. The other end of the resistor R_{MO1} is electrically coupled to the base of the transistor Q_{MO4} and one end of the resistor R_{MO2}. The emitter of the transistor Q_{MO4} and the other end of the resistor R_{MO2} are electrically coupled to the reference potential. The resistors R_{MO1} and R_{MO2} and the transistor Q_{MO4} generate constant voltage. This voltage is the voltage at the node N3.

The resistors R_{MO4} and R_{MO5} and the transistors Q_{MO6} and Q_{MO7} apply voltage to the node N4. That is, the resistors R_{MO4} and R_{MO5} and the transistors Q_{MO6} and Q_{MO7} provide bias to the collectors of the transistors Q_{MO1} and Q_{MO2}.

One end of the resistor R_{MO3} is electrically coupled to the power supply potential Vcc. The other end of the resistor R_{MO3} is electrically coupled to the collector and base of the transistor Q_{MO6}. That is, the transistor Q_{MO6} is diode-coupled. The emitter of the transistor Q_{MO6} is electrically coupled to the collector and base of the transistor Q_{MO7}. That is, the transistor Q_{MO7} is diode-coupled. The emitter of the transistor Q_{MO7} is electrically coupled to the reference potential. One end of the resistor R_{MO4} is electrically coupled to the other end of the resistor RMOs and the collector and base of the transistor Q_{MO6}. The other end of the resistor R_{MO4} is electrically coupled to the node N4. The transistors Q_{MO6} and Q_{MO7} generate a constant voltage. This voltage is the voltage at the node N4 via the resistor R_{MO4}.

The collector and base of the transistor Q_{MO5} are electrically coupled to the node N4. That is, the transistor Q_{MO5} is diode-coupled. The emitter of the transistor Q_{MO5} is electrically coupled to one end of the capacitor C_{MO1}. The other end of the capacitor C_{MO1} is electrically coupled to the reference potential.

The transistor Q_{MO5} outputs the signal S1 from the emitter. That is, the emitter voltage of the transistor Q_{MO5} corresponds to the signal S1 in the first embodiment. The capacitor C_{MO1} shunts the high-frequency components of the signal S1, thereby smoothing the signal S1.

The resistors R_{MO1}, R_{MO2}, and R_{MO3} and the transistor Q_{MO4} only need to output an approximately constant voltage and can be regarded as a constant voltage source. The resistor R_{MO3} and the transistors Q_{MO6} and Q_{MO7} only need to output an approximately constant voltage and can be regarded as a constant voltage source. The transistor Q_{MO5} only needs to produce an approximately constant voltage drop and can be regarded as a constant voltage source.

The low pass filter 43 includes a resistor RLPF and a capacitor CLPF.

One end of the resistor RLPF is electrically coupled to the emitter of the transistor Q_{MO5}. The other end of the resistor RLPF is electrically coupled to one end of the capacitor CLPF. The other end of the capacitor CLPF is electrically coupled to the reference potential.

The other end of the resistor RLPF and the one end of the capacitor CLPF are electrically coupled to the base of the transistor Q_{DE11}. The low pass filter 43 allows the low-frequency components of the signal S1 to pass through and outputs the resulting signal to the base of the transistor Q_{DE11}.

The low pass filter 42 includes a capacitor Cₑₙᵥ. One end of the capacitor Cₑₙᵥ is electrically coupled to the other end of the resistor R_{DEE1}, the other end of the resistor R_{DEE2}, and the collector of the transistor Q_{DE11}. The other end of the capacitor Cₑₙᵥ is electrically coupled to the reference potential.

The capacitor Cₑₙᵥ is charged or discharged due to the difference between the output current I1 of the detector circuit 22 and a collector current I2 of the transistor Q_{DE11}. The voltage across the capacitor Cₑₙᵥ is the signal S2. The capacitor Cₑₙᵥ terminates the high-frequency components (for example, carrier frequency signal components) of the signal S2 to the reference potential, thereby removing them and allowing only the low frequency components to pass. As a result, the capacitor Cₑₙᵥ can properly bias the subsequent bias circuits 18 and 19 and transistors (amplifying transistors) to be biased.

The bias circuit 18 includes transistors Q_{DE8}, Q_{DE9}, and Q_{DE10}. The bias circuit 19 (see FIG. 1) has the same circuit configuration as the bias circuit 18, and the description thereof is omitted.

The transistor Q_{DE9} is diode-coupled. The collector and base of the transistor Q_{DE9} are electrically coupled to the one end of the capacitor Cₑₙᵥ. The emitter of the transistor Q_{DE9} is electrically coupled to the collector and base of the transistor Q_{DE8}. The transistor Q_{DE8} is diode-coupled. The emitter of the transistor Q_{DE8} is electrically coupled to the reference potential. A current corresponding to the voltage across the capacitor Cₑₙᵥ flows through the transistors Q_{DE9} and Q_{DE8}.

The collector of the transistor Q_{DE10} is electrically coupled to the power supply potential Vcc. The base of the transistor Q_{DE10} is electrically coupled to the collector and base of the transistor Q_{DE9}. The emitter voltage of the transistor Q_{DE10} is outputted to the peak amplifier 16 (17) as a bias voltage BIAS₁₆ (BIAS₁₇).

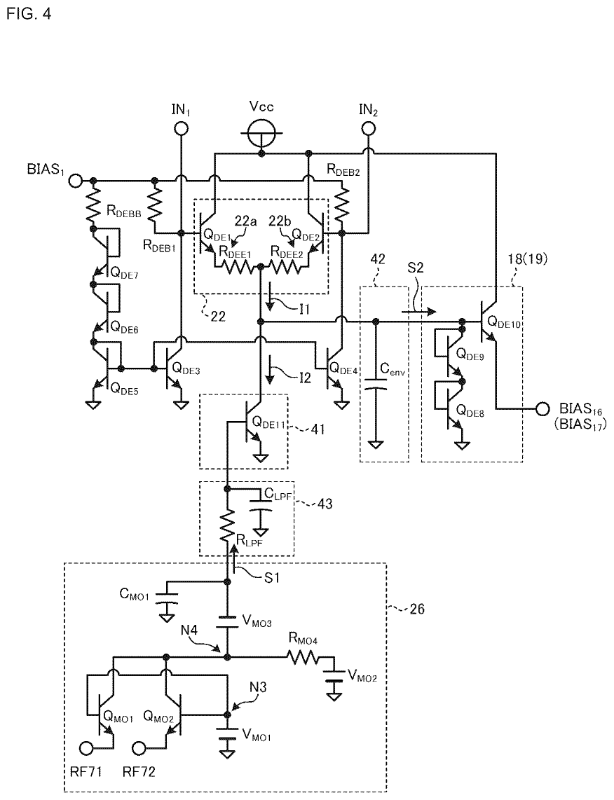

FIG. 4 illustrates an equivalent circuit of the specific example of the detector circuit and the drive-level detector circuit in the power amplifier circuit of the fifth embodiment.

A constant voltage source V_{MO1} in FIG. 4 corresponds to the resistors R_{MO1}, R_{MO2}, and R_{MO3} and the transistor Q_{MO4} in FIG. 3. A constant voltage source V_{MO2} in FIG. 4 corresponds to the resistor R_{MO3} and the transistors Q_{MO6} and Q_{MO7} in FIG. 3. A constant voltage source V_{MO3} in FIG. 4 corresponds to the transistor Q_{MO5} in FIG. 3.

### (Operation of Drive-level Detector Circuit)

The operation of the drive-level detector circuit 26 will be described with reference to the equivalent circuit in FIG. 4.

Generally, the output terminal voltage of the final-stage carrier amplifier 13 oscillates around the bias voltage with the voltage amplitude of the high-frequency signal. When the final-stage carrier amplifier 13 saturates, a situation occurs in which the voltage amplitude of the high-frequency signal increases and becomes nearly equal to the bias voltage. In such a situation, there is a moment during the oscillation period of the high-frequency signal when the output terminal voltage approaches 0 V. During this moment, no amplification is achieved, which leads to the phenomenon of amplifier saturation.

The circuit of the first embodiment uses this saturation principle and detects the drive level of the carrier amplifier 13.

Specifically, during the period of the high-frequency signals RF71 and RF72, the transistors Q_{MO1} and Q_{MO2} turn on only during the period when the voltages of the high-frequency signals RF71 and RF72 fall below the voltage of the constant voltage source V_{MO1} minus a voltage drop corresponding to the threshold voltages of the transistors Q_{MO1} and Q_{MO2}.

When the carrier amplifier 13 is operating well below saturation, there is no period during which the transistors Q_{MO1} and Q_{MO2} are on, and no collector current flows through the transistors Q_{MO1} and Q_{MO2}. Therefore, no current flows through the resistor R_{MO4}, and the resistor R_{MO4} does not cause a voltage drop. As a result, the voltage of the signal S1 is equal to the voltage of the constant voltage source V_{MO2} minus the voltage of the constant voltage source V_{MO3}.

When the amplitudes of the high-frequency signals RF71 and RF72 are large, there is a period during which the transistors Q_{MO1} and Q_{MO2} are on, and collector current flows. As a result, current flows through the resistor R_{MO4}, and the resistor R_{MO4} causes a voltage drop.

As the amplitudes of the high-frequency signals RF71 and RF72 become larger, the transistors Q_{MO1} and Q_{MO2} remain on for a longer period, thereby increasing the collector current. As a result, more current flows through the resistor R_{MO4}, and the resistor R_{MO4} causes a larger voltage drop.

Therefore, as the drive level of the carrier amplifier 13 increases, the voltage of the signal S1 becomes equal to the voltage observed when the high-frequency signals RF71 and RF72 are small signals, minus the voltage drop across the resistor R_{MO4}.

Next, the operation of the detector circuit 22 will be described.

When the high-frequency signal IN₁ is greater than or equal to the threshold voltage of the transistor Q_{DE1}, the transistor Q_{DE1} turns on and outputs emitter current. When the high-frequency signal IN₂ is greater than or equal to the threshold voltage of the transistor Q_{DE2}, the transistor Q_{DE2} turns on and outputs emitter current.

That is, as the amplitudes of the high-frequency signals IN₁ and IN₂ increase, (as the power of the high-frequency signal RFin increases), the output current of the detector circuit 22 increases. As the amplitudes of the high-frequency signals IN₁ and IN₂ decrease, (as the power of the high-frequency signal RFin decreases), the output current of the detector circuit 22 decreases.

On the other hand, as described above, the voltage of the signal S1 is relatively low when the drive level of the carrier amplifier 13 is relatively high (when close to saturation) and is relatively high when the drive level of the carrier amplifier 13 is relatively low (when the amplification ratio is reduced).

That is, the relatively higher (the closer to the saturation) the drive level of the carrier amplifier 13, the smaller the collector current I2 of the transistor Q_{DE11}. The relatively lower the drive level of the carrier amplifier 13 (the lower the amplification ratio), the larger the collector current I2 of the transistor Q_{DE11}.

In summary, the voltage across the capacitor Cₑₙᵥ tends to increase as the drive level of the carrier amplifier 13 becomes relatively higher (closer to saturation). Conversely, the voltage across the capacitor Cₑₙᵥ is less likely to increase as the drive level of the carrier amplifier 13 becomes relatively lower (the amplification ratio becomes lower). Furthermore, the voltage across the capacitor Cₑₙᵥ tends to increase as the power of the high-frequency signal RFin becomes higher. The voltage across the capacitor Cₑₙᵥ is less likely to increase as the power of the high-frequency signal RFin becomes lower.

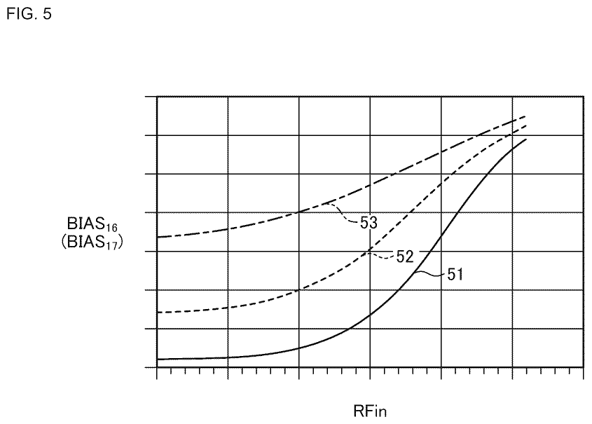

FIG. 5 illustrates an example of the relationship between high-frequency signal power of the power amplifier circuit in the first embodiment and bias voltage applied to the peak amplifier. In FIG. 5, the horizontal axis represents the power of the high-frequency signal RFin, and the vertical axis represents the bias voltage BIAS₁₆ (BIAS₁₇) applied to the peak amplifier 16 (17) by the bias circuit 18 (19).

A waveform 51 represents variation in the bias voltage BIAS₁₆ (BIAS₁₇) when the drive level of the carrier amplifier 13 is relatively low. A waveform 52 represents variation in the bias voltage BIAS₁₆ (BIAS₁₇) when the drive level of the carrier amplifier 13 is relatively intermediate. A waveform 53 represents the variation in the bias voltage BIAS₁₆ (BIAS₁₇) when the drive level of the carrier amplifier 13 is relatively high.

In the case where the drive level of the carrier amplifier 13 is relatively high, as represented by the waveform 53, the detector circuit 22 can activate the peak amplifiers 16 and 17 even if the power of the high-frequency signal RFin is low. In the case where the drive level of the carrier amplifier 13 is relatively low, as represented by the waveform 51, the detector circuit 22 can delay the activation of the peak amplifiers 16 and 17 until the power of the high-frequency signal RFin becomes high.

Therefore, in the case where the drive level of the carrier amplifier 13 is relatively high (close to saturation), the current of the constant-current circuit 41 needs to be reduced so that the peak amplifiers 16 and 17 can be activated even if the power of the high-frequency signal RFin is low. Conversely, in the case where the drive level of the carrier amplifier 13 is relatively low, the current of the constant-current circuit 41 needs to be increased because the peak amplifiers 16 and 17 do not need to be activated until the power of the high-frequency signal RFin becomes high. That is, the configuration in which a voltage BIAS₂ applied to the constant-current circuit 41 changes complementarily to the drive level of the carrier amplifier 13 enables the intended operation of the overall circuit.

The response of the detector circuit 22 becomes faster for the following reason.

First, the first emitter-follower circuit 22a and the second emitter-follower circuit 22b operate differentially. Therefore, the capacitance of the capacitor Cₑₙᵥ can be made smaller than in the configuration where an emitter-follower circuit operates in single-ended mode. The delay in the capacitor Cₑₙᵥ can thereby be reduced, and the change in the signal S2 can be accelerated. That is, the response of the detector circuit 22 becomes faster.

Second, an emitter-follower circuit is able to output large current. Therefore, each of the first emitter-follower circuit 22a and the second emitter-follower circuit 22b can output large current. That is, the output current I1 of the detector circuit 22 can be large. The detector circuit 22 can thereby quickly charge the capacitor Cₑₙᵥ. This means that the rising response of the detector circuit 22 becomes faster.

Third, the transistor Q_{DE11} can discharge the capacitor Cₑₙᵥ by means of a constant current (the collector current I2). Therefore, the transistor Q_{DE11} can quickly discharge the capacitor Cₑₙᵥ. That is, the falling response of the detector circuit 22 becomes faster.

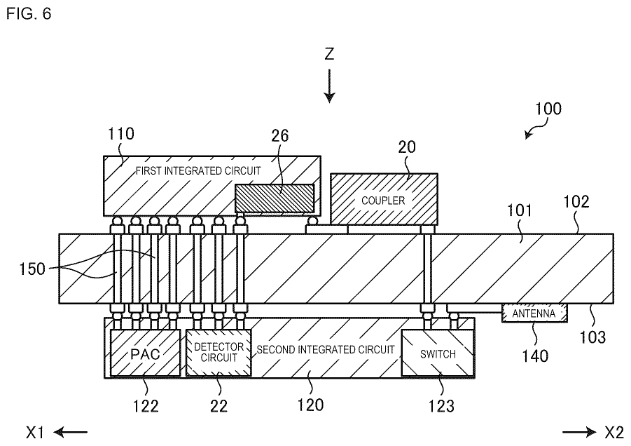

FIG. 6 is a schematic diagram schematically illustrating a cross-sectional structure of the power amplification device of the first embodiment. FIG. 7 is a plan view of the power amplification device of the first embodiment. FIG. 8 is a view of a second integrated circuit of the first embodiment when viewed from the substrate. Next, the layout of the power amplification device 100 will be described. In the example described below, the power amplification device 100 includes only the Doherty amplifier 10, and the amplifier 2 (see FIG. 1) and the bias circuit 3 (see FIG. 1) are included in another device. That is, the radio-frequency signal inputted to the power amplification device 100 (the Doherty amplifier 10) below is the signal RF1 (see FIG. 1) outputted from the amplifier 2.

As illustrated in FIG. 6, the power amplification device 100 includes a substrate 101, a first integrated circuit 110, a second integrated circuit 120, the coupler 20, and an antenna 140.

The substrate 101 is a printed circuit board (PCB). The substrate 101 includes a first surface 102 and a second surface 103, which faces opposite to the first surface 102. Hereinafter, the direction in which the first surface 102 and the second surface 103 are arranged is referred to as a thickness direction. The view of the power amplification device 100 in a direction (a direction facing the first surface 102) of arrow Z illustrated in FIG. 6 is referred to as plan view.

On the first surface 102, the first integrated circuit 110 and the coupler 20 are provided. On the second surface 103, the second integrated circuit 120 and the antenna 140 are provided. In the substrate 101, a plurality of through vias 150 are provided, which pass through the substrate 101 in the thickness direction. Both ends of each through via 150 are provided with electrodes arranged on the first surface 102 or the second surface 103. Components arranged on the first surface 102 and components arranged on the second surface 103 are electrically coupled to each other when the components are coupled to electrodes at respective ends of the through vias 150. Hereinafter, an axis that is parallel to the first surface 102 and along which the first integrated circuit 110 and the coupler 20 are arranged is referred to as a longitudinal axis. The direction in which the first integrated circuit 110 is disposed, when viewed from the coupler 20, is referred to as a first longitudinal direction X1. The direction opposite to the first longitudinal direction X1 is referred to as a second longitudinal direction X2.

As illustrated in FIG. 7, the substrate 101 is quadrangular in plan view. In the present disclosure, the substrate 101 does not need to be rectangular. Hereinafter, an axis that is parallel to the first surface 102 and intersects with the longitudinal axis is referred to as a transverse axis. In plan view of the first surface 102, the direction along the transverse axis in which the right hand is positioned is referred to as a first transverse direction Y1, and the direction opposite to the first transverse direction Y1 is referred to as a second transverse direction Y2.

The first integrated circuit 110 is a heterojunction bipolar transistor (HBT) circuit. The first integrated circuit 110 includes the splitter 11, the carrier amplifier 12, the carrier amplifier 13, the bias circuit 14 (see FIG. 1), the bias circuit 15 (see FIG. 1), the peak amplifier 16, the peak amplifier 17, the bias circuit 18, and the bias circuit 19 (see FIG. 1), and the drive-level detector circuit 26.

Among the bias circuits, FIG. 7 and subsequent drawings illustrate only the bias circuit 18 and do not illustrate the other bias circuits 14, 15, and 19 for easy understanding of the drawings. In the description of the first embodiment, the carrier amplifier 13 and the peak amplifier 17 are single-ended amplifiers. Furthermore, in the example of the first embodiment, the signal S2 outputted from the detector circuit 22 is supplied to only the bias circuit 18. In FIG. 7 and subsequent drawings, arrows extending between circuits indicate paths along which signals are transmitted.

The splitter 11 is disposed close to the end of the first integrated circuit 110 in the first longitudinal direction X1 in the center of the first integrated circuit 110 along the transverse axis. The radio frequency signal (the high-frequency signal RF1) inputted to the first integrated circuit 110 from the outside is received by the splitter 11.

The carrier amplifiers 12 and 13 and the peak amplifiers 16 and 17 are arranged on the second longitudinal direction X2 side of the splitter 11. The carrier amplifiers 12 and 13 are arranged on the second transverse direction Y2 side of the center of the first integrated circuit 110 along the transverse axis. On the other hand, the peak amplifiers 16 and 17 are arranged on the first transverse direction Y1 side of the center of the first integrated circuit 110 along the transverse axis.

Starting from the splitter 11, the carrier amplifier 12 and the carrier amplifier 13 are arranged in this order. The high-frequency signal RF2 (see FIG. 1) outputted from the splitter 11 is therefore transmitted in the second longitudinal direction X2 via the carrier amplifiers 12 and 13 to be inputted to the coupler 20. In a similar manner, starting from the splitter 11, the peak amplifier 16 and the peak amplifier 17 are arranged in this order. The high-frequency signal RF5 (see FIG. 1) outputted from the splitter 11 is transmitted in the second longitudinal direction X2 via the peak amplifiers 16 and 17 to be inputted to the coupler 20.

On the path from the splitter 11 to the carrier amplifier 12, an electrode of a first through via 151, which is included in the through vias 150, is provided. The first through via 151 transmits the high-frequency signal RF1 to the second surface 103 side.

The drive-level detector circuit 26 is disposed between the carrier amplifier 13 and the peak amplifier 17. The drive-level detector circuit 26 is disposed close to the carrier amplifier 13. The drive-level detector circuit 26 is therefore adjacent to the carrier amplifier 13, and a path 104 from the carrier amplifier 13 to the drive-level detector circuit 26 is short. As a result, the time required for the detector circuit 22 to detect a load variation is reduced.

The output of the drive-level detector circuit 26 is transmitted to the second surface 103 side via a second through via 152, which is included in the through vias 150. In plan view, the second through via 152 overlaps the drive-level detector circuit 26. That is, an electrode of the second through via 152 is directly below the drive-level detector circuit 26. This shortens the path for the signal S1 outputted from the drive-level detector circuit 26 to reach the second surface 103 side. From this aspect as well, the time required for the detector circuit 22 to detect a load variation is reduced.

The length of the second integrated circuit 120 along the transverse axis is shorter than that of the first integrated circuit 110 (see the dashed line in FIG. 7). The second integrated circuit 120 therefore has an oblong shape elongated along the longitudinal axis in plan view. The second integrated circuit 120 is disposed on the second transverse direction Y2 side of the center of the substrate 101 along the transverse axis. In plan view, therefore, the second integrated circuit 120 overlaps the carrier amplifiers 12 and 13 and the drive-level detector circuit 26.

The second integrated circuit 120 is a complementary metal-oxide semiconductor (CMOS) circuit. As illustrated in FIG. 8, the second integrated circuit 120 includes the detector circuit 22, a power amplifier controller (PAC) 122, and a switch 123.

The PAC 122 supplies a reference bias to the bias circuits 14, 15, 18, and 19. The PAC 122 outputs the reference bias to the first surface 102 side via four third through vias 153, which are included in the through vias 150. Electrodes of the four third through vias 153 are provided directly below the PAC 122.

The detector circuit 22 is included in the second integrated circuit 120 (on the second surface 103 side). If the detector circuit 22 is provided on the same surface (the first surface 102) as the carrier amplifier 13 and the peak amplifier 17, the detector circuit 22 is susceptible to heat generated by the carrier amplifier 13 and the peak amplifier 17. In the first embodiment, the detector circuit 22 is less susceptible to heat generated by the carrier amplifier 13 and the peak amplifier 17.

The detector circuit 22 is located close to the end of the second integrated circuit 120 in the first longitudinal direction X1. The detector circuit 22 is also disposed in the first longitudinal direction X1 side of the carrier amplifier 13 and the peak amplifier 17. That is, when viewed from the carrier amplifier 12 and the peak amplifier 16, the detector circuit 22 is disposed on the side opposite to the carrier amplifier 13 and the peak amplifier 17. From this aspect as well, the detector circuit 22 is distant from the carrier amplifier 13 and the peak amplifier 17 and is less susceptible to heat generated by the carrier amplifier 13 and the peak amplifier 17.

The first through via 151 is provided directly below the detector circuit 22, and the path from the splitter 11 to the detector circuit 22 is short.

In plan view, the detector circuit 22 overlaps a fourth through via 154, which is included in the through vias 150. That is, the electrodes of the fourth through via 154 are provided directly below the detector circuit 22. The detector circuit 22 outputs the signal S2 to the first surface 102 side via the fourth through via 154 to supply the signal S2 to the bias circuit 18. The detector circuit 22 of the first embodiment is longer along the transverse axis than along the longitudinal axis. The output terminal (not illustrated) of the detector circuit 22 and the fourth through via 154 are located close to the end of the second integrated circuit 120 in the first transverse direction Y1, or close to the bias circuit 18. Therefore, a path 105 from the detector circuit 22 to the bias circuit 18 is short (see FIG. 7). This shortens the time between when the detector circuit 22 detects a load variation and when the peak amplifier 16 is activated.

The switch 123 opens or closes the path from the coupler 20 to the antenna 140. To be more specific, one end of the switch 123 is coupled to the coupler 20 via a fifth through via 155, which is included in the through vias 150. The other end of the switch 123 is coupled to the antenna 140 via a wire 141. When the switch 123 is closed, the high-frequency signal RFout outputted from the coupler 20 is outputted from the antenna 140 as electromagnetic waves.

As described above, according to the layout of the first embodiment, the detector circuit 22 is less susceptible to heat generated by the carrier amplifier 13 and the peak amplifier 17. This suppresses degradation in the characteristics of the detector circuit 22. Furthermore, the path of the signal S1 (the path from the carrier amplifier 13 to the detector circuit 22) and the path of the signal S2 (the path from the detector circuit 22 to the bias circuit 18) are short. As a result, the fast response speed to load variations suppresses degradation in the quality of high-frequency output signals.

The first embodiment has been described hereinabove, but the present disclosure is not limited thereto. Next, first to fifth modifications with layouts different from that of the first embodiment will be described. These modifications will be described in terms of only the differences from the first embodiment.

### (First Modification)

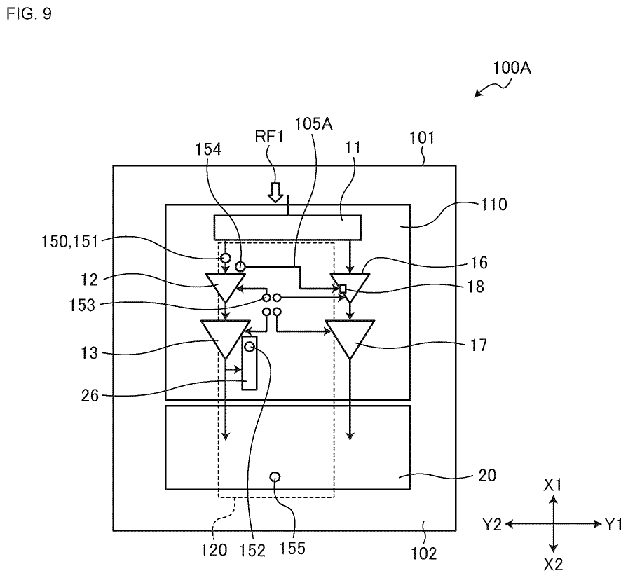

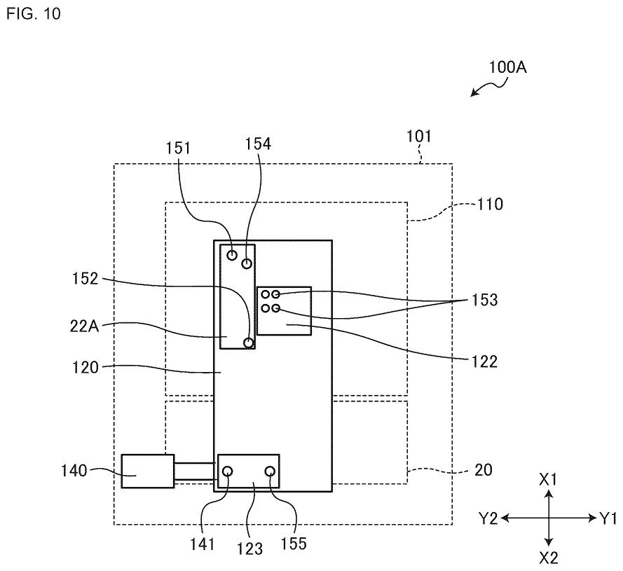

FIG. 9 is a plan view of a power amplification device of a first modification. FIG. 10 is a view of a second integrated circuit of the first modification when viewed from the substrate. A power amplification device 100A of the first modification differs from the power amplification device 100 of the first embodiment in that the position of a detector circuit 22A is changed from that of the detector circuit 22. To be specific, the detector circuit 22 of the first embodiment is disposed so as to be elongated along the transverse axis, while the detector circuit 22A of the first modification is disposed so as to be elongated along the longitudinal axis. The second through via 152 is disposed directly below the end portion of the detector circuit 22A in the second longitudinal direction X2. That is, the detector circuit 22A and the drive-level detector circuit 26 are coupled by the second through via 152 (the through via 150). Therefore, the path from the drive-level detector circuit 26 to the detector circuit 22A is shortened, thereby increasing the response speed to load variations.

In addition, the first through via 151 is provided directly below the end portion of the detector circuit 22A in the first longitudinal direction X1 as in the first embodiment, and the path from the splitter 11 to the detector circuit 22 is short. According to the first modification, the end portion of the detector circuit 22A in the second longitudinal direction X2 is close to the carrier amplifier 13 and the peak amplifier 17. Therefore, the detector circuit 22A is more susceptible to heat generated by the carrier amplifier 13 and the peak amplifier 17 than that of the first embodiment. Furthermore, according to the first modification, the fourth through via 154 is shifted toward the second transverse direction Y2 compared to that in the first embodiment. Therefore, the path 105A from the detector circuit 22A to the bias circuit 18 is longer than the path 105 in the first embodiment.

### (Second Modification)

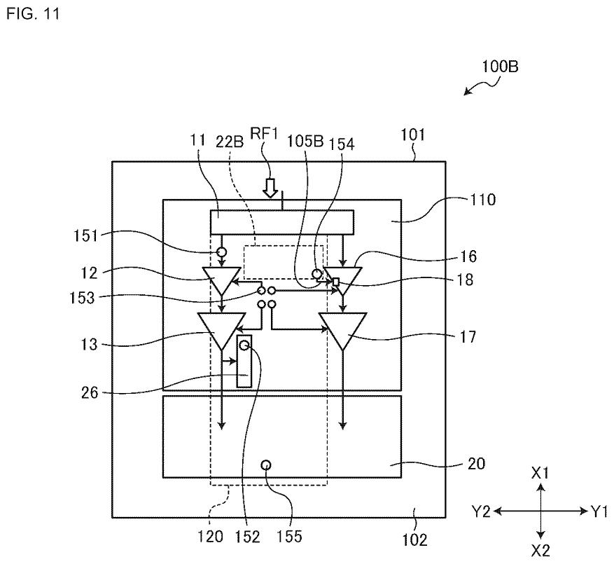

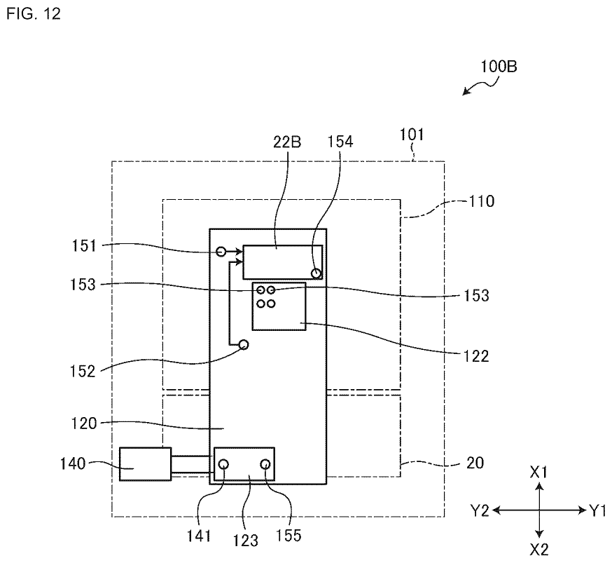

FIG. 11 is a plan view of a power amplification device of a second modification. FIG. 12 is a view of a second integrated circuit of the second modification when viewed from the substrate. A power amplification device 100B of the second modification differs from the power amplification device 100 of the first embodiment in that the position of the detector circuit 22B is disposed between the carrier amplifier 12 and the peak amplifier 16. Furthermore, the power amplification device 100B of the second modification differs from the power amplification device 100 of the first embodiment in that the fourth through via 154 is adjacent to the bias circuit 18 in the second transverse direction Y2.

According to the second modification, the output terminal (not illustrated) of the detector circuit 22B and the fourth through via 154 are in proximity to the peak amplifier 16. That is, a path 105B from the detector circuit 22B to the bias circuit 18 is short. As a result, the response speed to load variations is fast, thereby suppressing degradation in the quality of high-frequency output signals.

### (Third Modification)

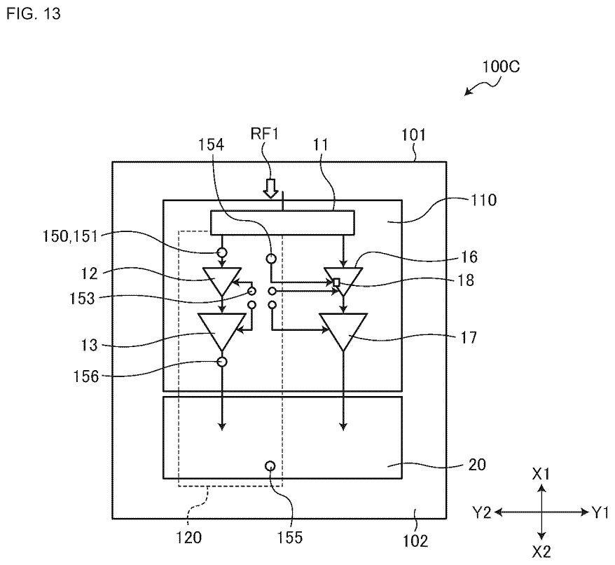

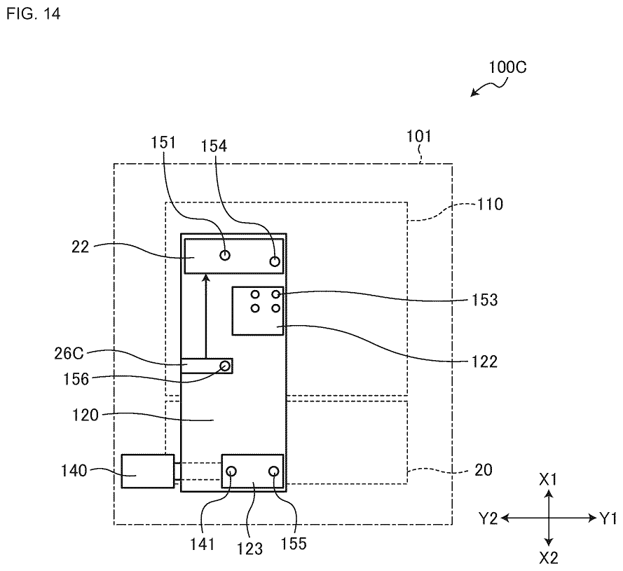

FIG. 13 is a plan view of a power amplification device of a third modification. FIG. 14 is a view of a second integrated circuit of the third modification when viewed from the substrate. A power amplification device 100C of the third modification differs from the power amplification device 100 of the first embodiment in that a drive-level detector circuit 26C is included in the second integrated circuit 120. That is, the drive-level detector circuit 26C is provided on the second surface 103 side of the substrate 101.

On the path from the carrier amplifier 13 to the coupler 20, an electrode of a sixth through via 156, which is included in the through vias 150, is provided. That is, in plan view, the drive-level detector circuit 26C overlaps the sixth through via 156, and the high-frequency signal RF4 (see FIG. 1) is inputted to the drive-level detector circuit 26C via the sixth through via 156. Therefore, according to the third modification, the path from the carrier amplifier 13 to the drive-level detector circuit 26 is short, and the response speed to load variations is fast.

### (Fourth Modification)

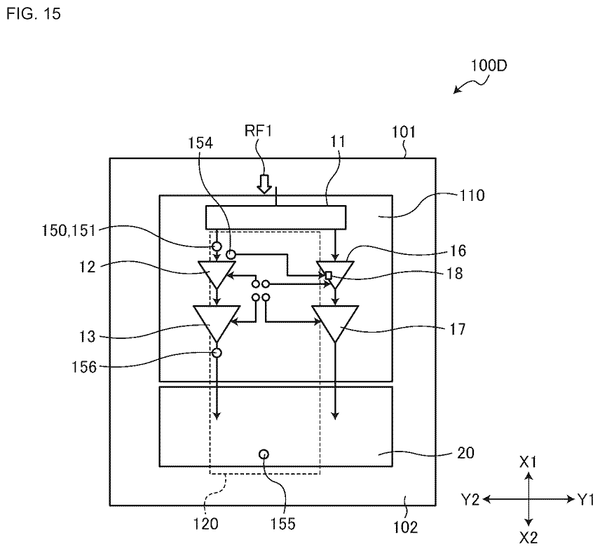

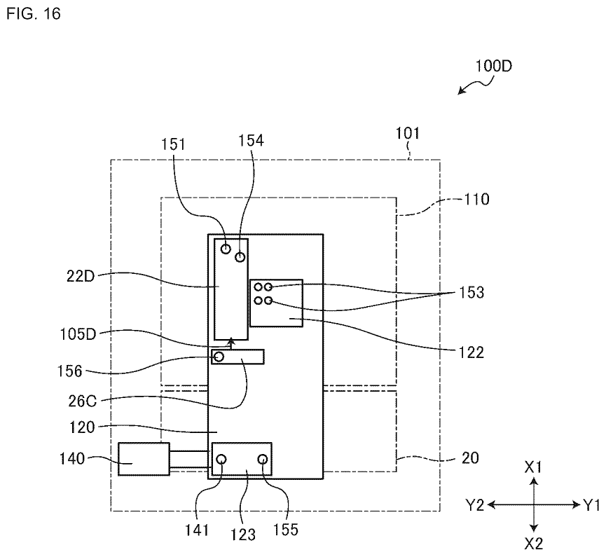

FIG. 15 is a plan view of a power amplification device of a fourth modification. FIG. 16 is a view of a second integrated circuit of the fourth modification when viewed from the substrate. A power amplification device 100D of the fourth modification differs from the power amplification device 100C of the third modification in that the position of a detector circuit 22D is changed from that of the detector circuit 22. The detector circuit 22 of the third modification is disposed so as to be elongated along the transverse axis, while the detector circuit 22D of the fourth modification is disposed so as to be elongated along the longitudinal axis. According to the fourth modification, the end portion of the detector circuit 22D in the second longitudinal direction X2 is adjacent to the drive-level detector circuit 26C. Therefore, a path 105D from the drive-level detector circuit 26C to the detector circuit 22D is short, and the response speed to load variations is fast.

### (Fifth Modification)

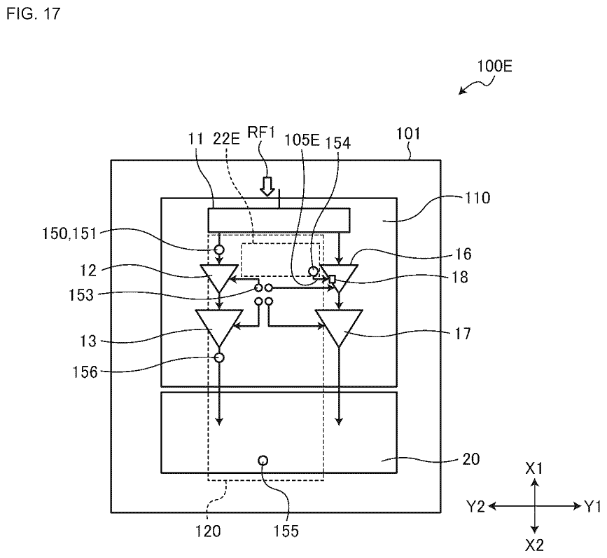

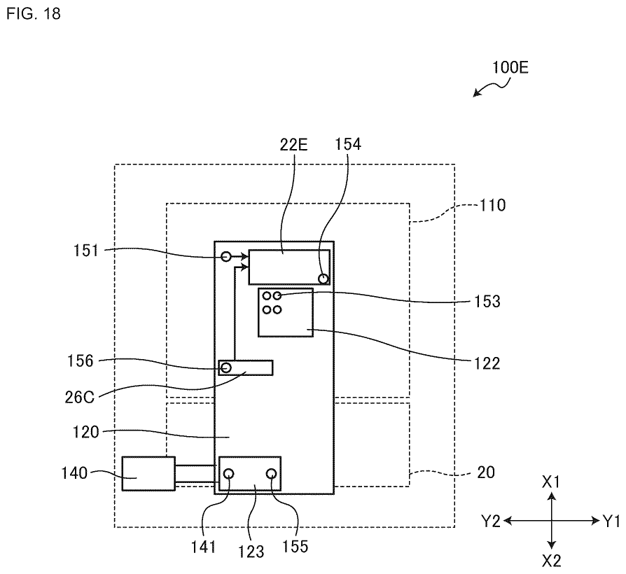

FIG. 17 is a plan view of a power amplification device of a fifth modification. FIG. 18 is a view of a second integrated circuit of the fifth modification when viewed from the substrate. A power amplification device 100E of the fifth modification differs from the power amplification device 100C of the third modification in that the position of the detector circuit 22B is disposed between the carrier amplifier 12 and the peak amplifier 16. Furthermore, the power amplification device 100E of the fifth modification differs from the power amplification device 100C of the third modification in that the fourth through via 154 is located at a position adjacent to the bias circuit 18 in the second transverse direction Y2.

According to the fifth modification, the output terminal (not illustrated) of the detector circuit 22E and the fourth through via 154 are in proximity to the peak amplifier 16 (the bias circuit 18). That is, a path 105E from the detector circuit 22B to the bias circuit 18 is short. Therefore, the response speed to load variations is fast, thereby suppressing degradation in the quality of high-frequency output signals.

The first to fifth modifications have been described above, but in the present disclosure, the substrate 101 may be provided with a thermal via. Next, a sixth modification will be described, in which a thermal via is provided for the power amplification device 100 of the first embodiment.

### (Sixth Modification)

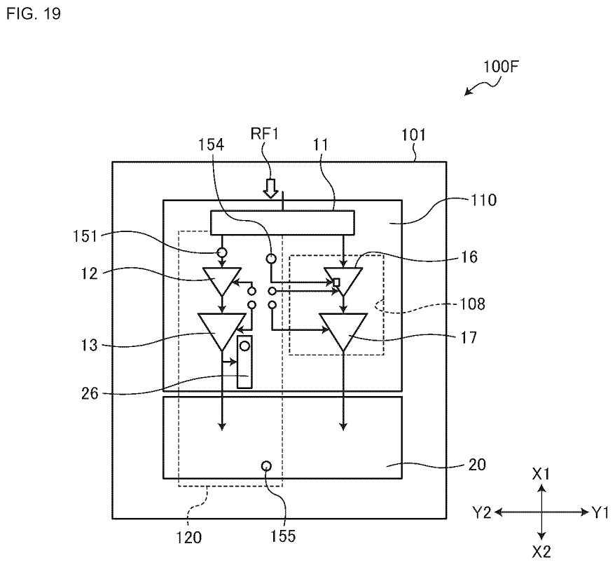

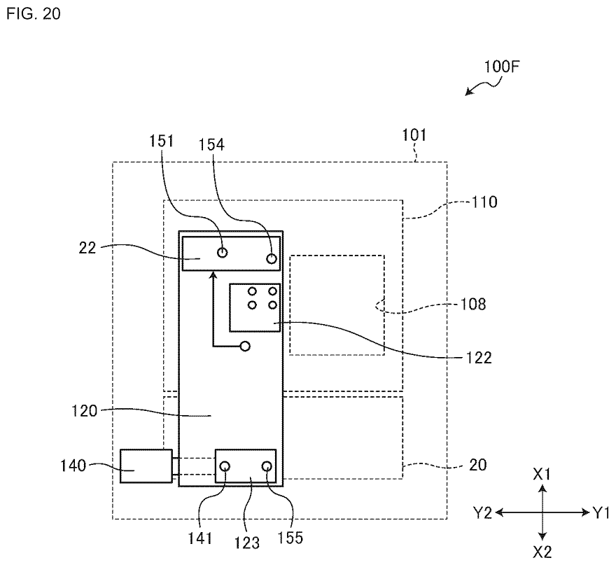

FIG. 19 is a plan view of a power amplification device of a sixth modification. FIG. 20 is a view of a second integrated circuit of the sixth modification when viewed from the substrate. As illustrated in FIGS. 19 and 20, the substrate 101 of a power amplification device 100F of the sixth modification is provided with a plurality of thermal vias 108, which pass through the substrate 101 in the thickness direction. The thermal via 108 is rectangular in plan view. The thermal via 108 is disposed on the first transverse direction Y1 side of the center of the substrate 101 along the transverse axis. The thermal via 108 therefore does not overlap the second integrated circuit 120. In plan view, the thermal via 108 overlaps the peak amplifiers 16 and 17. As a result, the peak amplifiers 16 and 17 are cooled via the thermal via 108 by the outside air on the second surface 103 of the substrate 101.

In the description of the first embodiment and the first to sixth modifications, the single-ended carrier amplifier 13 and peak amplifier 17 are exemplified. In the present disclosure, the carrier amplifier 13 and the peak amplifier 17 may be each composed of a pair of differential amplifiers. Next, seventh to twelfth modifications will be described, in which differential amplifiers are used for the carrier amplifier 13 and the peak amplifier 17.

### (Seventh Modification)

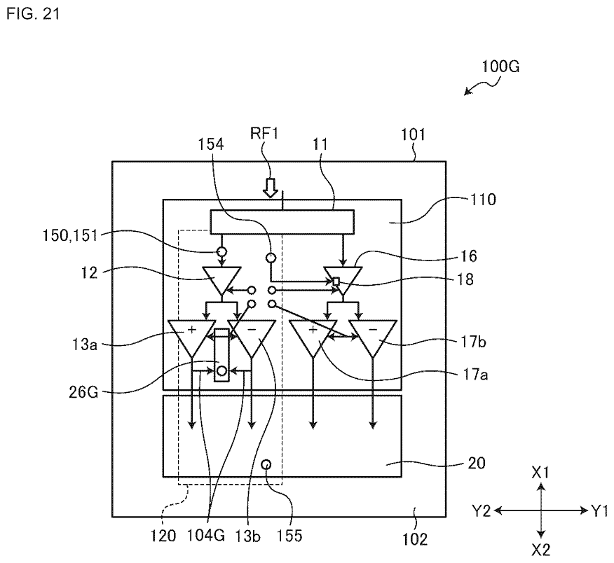

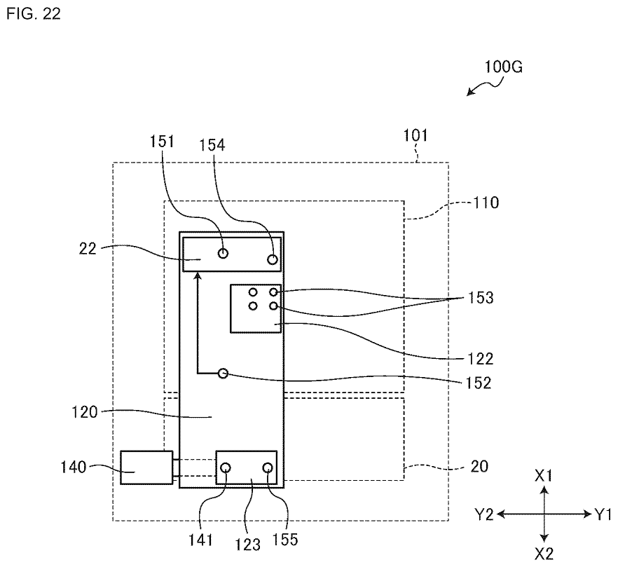

FIG. 21 is a plan view of a power amplification device of a seventh modification. FIG. 22 is a view of a second integrated circuit of the seventh modification when viewed from the substrate. A power amplifier 100G of the seventh modification differs from the power amplification device 100 of the first embodiment in including a pair of differential amplifiers (a first differential amplifier 13a and a second differential amplifier 13b) instead of the carrier amplifier 13. The power amplifier 100G of the seventh modification differs from the power amplification device 100 of the first embodiment in including a pair of differential amplifiers (a first differential amplifier 17a and a second differential amplifier 17b) instead of the peak amplifier 17. The power amplifier 100G of the seventh modification differs from the power amplification device 100 of the first embodiment in that the position of the drive-level detector circuit 26G is changed from that of the drive-level detector circuit 26. The differences will be described in detail below.

The first differential amplifier 13a and the second differential amplifier 13b are arranged between the carrier amplifier 12 and the coupler 20. The first differential amplifier 17a and the second differential amplifier 17b are arranged between the peak amplifier 16 and the coupler 20. Starting from the second transverse direction Y2 side, the first differential amplifier 13a, the second differential amplifier 13b, the first differential amplifier 17a, and the second differential amplifier 17b are arranged in this order.

The drive-level detector circuit 26G is disposed between the first differential amplifier 13a and the second differential amplifier 13b. Therefore, paths 104G from the first differential amplifier 13a and the second differential amplifier 13b to the drive-level detector circuit 26G are short. In the seventh modification, as in the first embodiment, the response speed to load variations is fast, thereby suppressing degradation in the quality of high-frequency output signals.

### (Eighth Modification)

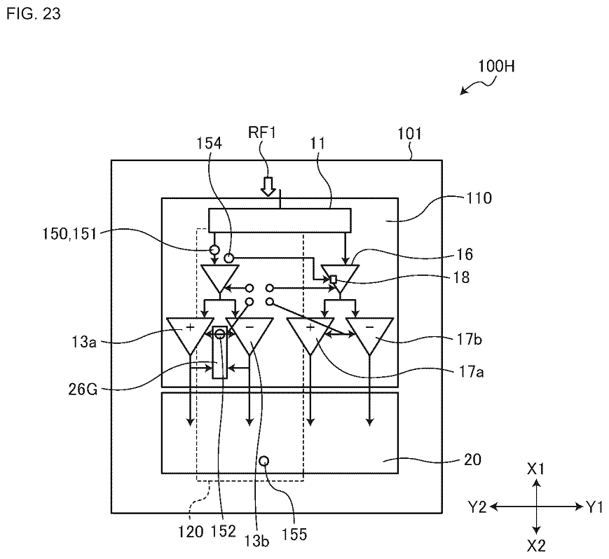

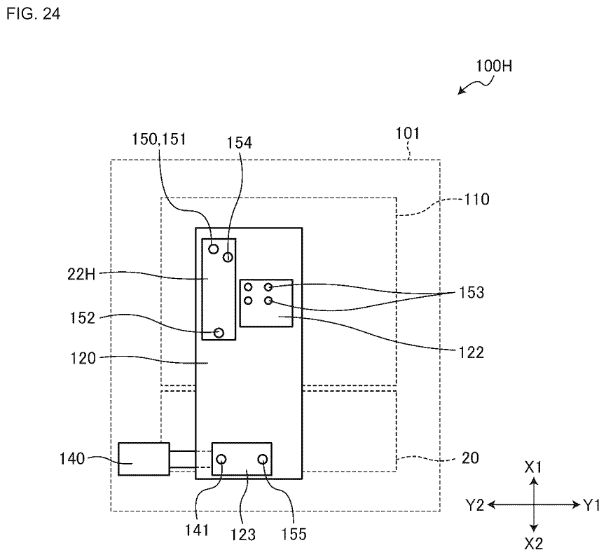

FIG. 23 is a plan view of a power amplification device of an eighth modification. FIG. 24 is a view of a second integrated circuit of the eighth modification when viewed from the substrate. A power amplification device 100H of the eighth modification differs from the power amplifier 100G of the seventh modification in that the position of a detector circuit 22H is changed from that of the detector circuit 22. The detector circuit 22 of the seventh modification is disposed so as to be elongated along the transverse axis, while the detector circuit 22A of the eighth modification is disposed so as to be elongated along the longitudinal axis. Therefore, the second through via 152 is disposed directly below the end portion of the detector circuit 22H in the second longitudinal direction X2 and is coupled to the detector circuit 22H. According to the eighth modification, the path from the drive-level detector circuit 26G to the detector circuit 22H is short, and the response speed to load variations is fast.

### (Ninth Modification)

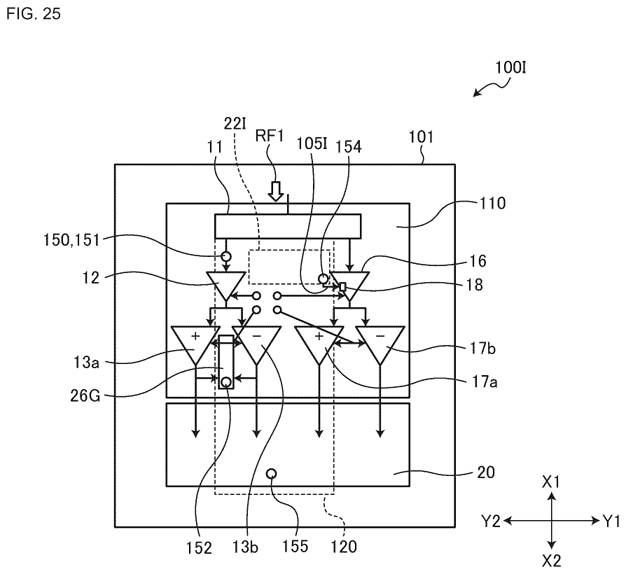

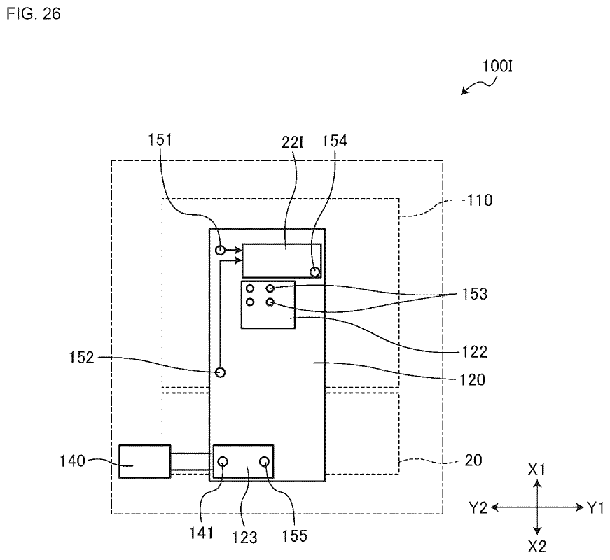

FIG. 25 is a plan view of a power amplification device of a ninth modification. FIG. 26 is a view of a second integrated circuit of the ninth modification when viewed from the substrate. A power amplification device 100I of the ninth modification differs from the power amplifier 100G of the seventh modification in that a detector circuit 22I is disposed between the carrier amplifier 12 and the peak amplifier 16. Furthermore, the power amplification device 100I of the ninth modification differs from the power amplification device 100C of the third modification in that the fourth through via 154 is located at a position adjacent to the bias circuit 18 in the second transverse direction Y2. According to this fifth modification, the output terminal (not illustrated) of the detector circuit 22I and the fourth through via 154 are in proximity to the peak amplifier 16 (the bias circuit 18). That is, a path 1051 from the detector circuit 22I to the bias circuit 18 is short. As a result, the response speed to load variations is fast, thereby suppressing degradation in the quality of high-frequency output signals.

### (Tenth Modification)

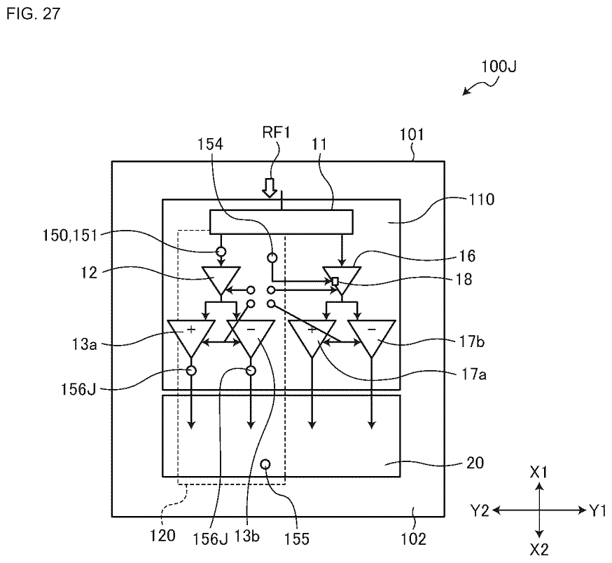

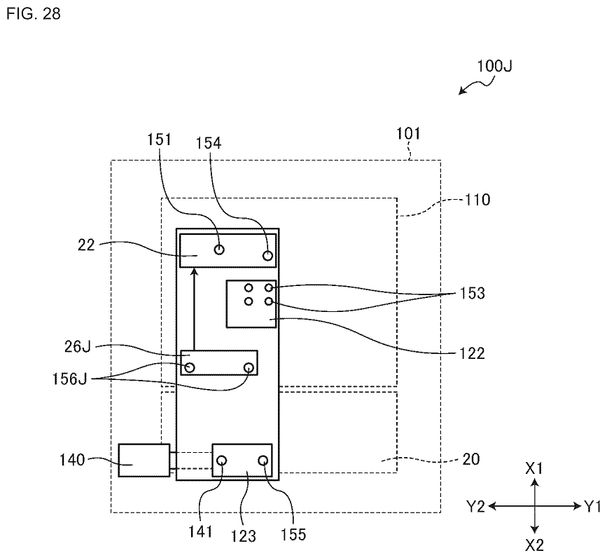

FIG. 27 is a plan view of a power amplification device of a tenth modification. FIG. 28 is a view of a second integrated circuit of the tenth modification when viewed from the substrate. The power amplification device 100J of the tenth modification differs from the power amplifier 100G of the seventh modification in that a drive-level detector circuit 26J is included in the second integrated circuit 120. That is, the drive-level detector circuit 26J is provided on the second surface 103 side of the substrate 101. Furthermore, on the path from the first differential amplifier 13a to the coupler 20, a sixth through via 156J, which is included in the through vias 150, is provided. On the path from the second differential amplifier 13b to the coupler 20, another sixth through via 156J is provided. The drive-level detector circuit 26J overlaps the two sixth through vias 156J. The high-frequency signal RF4 (see FIG. 1) is inputted to the drive-level detector circuit 26J via the sixth through vias 156J. According to the tenth modification, as described above, the paths from the first differential amplifier 13a and the second differential amplifier 13b to the drive-level detector circuit 26 are short, and the response speed to load variations is fast.

### (Eleventh Modification)

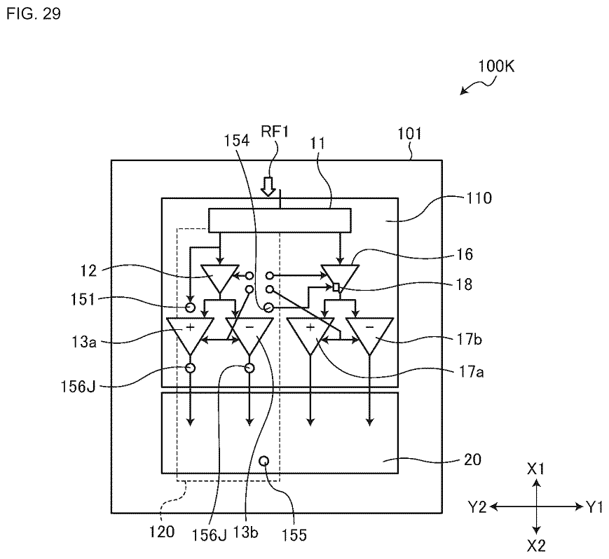

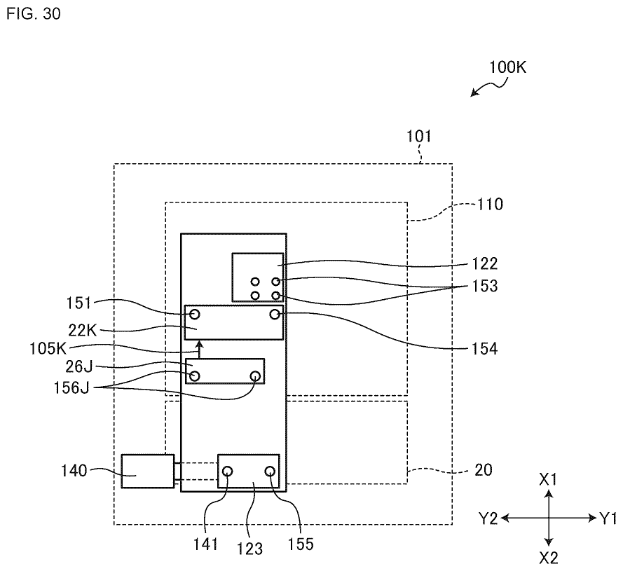

FIG. 29 is a plan view of a power amplification device of an eleventh modification. FIG. 30 is a view of a second integrated circuit of the eleventh modification when viewed from the substrate. A power amplification device 100K of the eleventh modification differs from the power amplification device 100J of the tenth modification in that the arrangement of a detector circuit 22K is changed from that of the detector circuit 22. The detector circuit 22 of the tenth modification is disposed on the first longitudinal direction X1 side of the PAC 122, while the detector circuit 22K of the eleventh modification is disposed on the second longitudinal direction X2 side of the PAC 122. According to this eleventh modification, the detector circuit 22K and the drive-level detector circuit 26J are in proximity to each other, and a path 105K from the drive-level detector circuit 26J to the detector circuit 22K is short. As a result, the response speed to load variations is fast. The first through via 151 of the eleventh modification is disposed on the second longitudinal direction X2 side of the carrier amplifier 12 so as to overlap the detector circuit 22K.

### (Twelfth Modification)

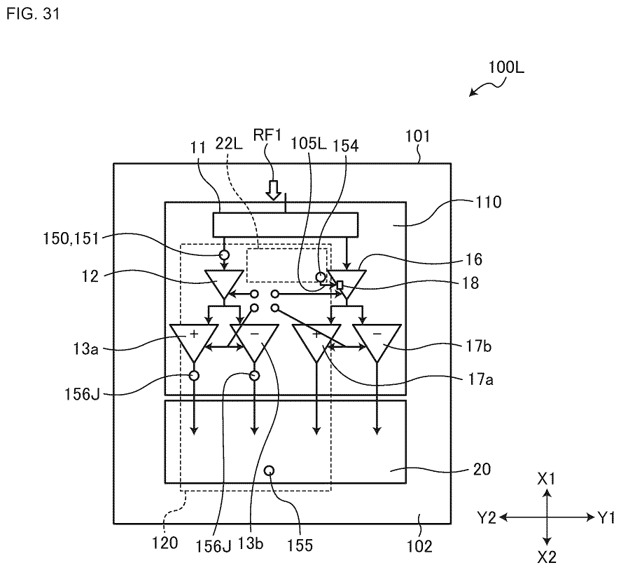

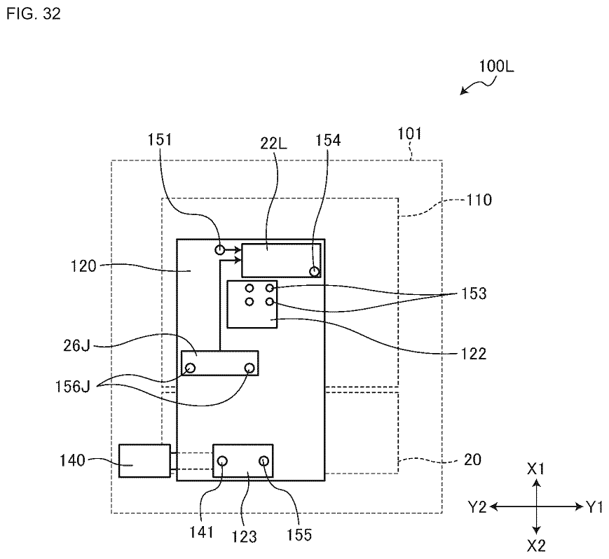

FIG. 31 is a plan view of a power amplification device of a twelfth modification. FIG. 32 is a view of a second integrated circuit of the twelfth modification when viewed from the substrate. A power amplification device 100L of the twelfth modification differs from the power amplification device 100J of the tenth modification in that a detector circuit 22L is disposed between the carrier amplifier 12 and the peak amplifier 16. Furthermore, the power amplification device 100L of the twelfth modification differs from the power amplification device 100J of the tenth modification in that the fourth through via 154 is located at a position adjacent to the bias circuit 18 in the second transverse direction Y2. According to the twelfth modification, the output terminal (not illustrated) of the detector circuit 22L and the fourth through via 154 are in proximity to the peak amplifier 16 (the bias circuit 18). That is, a path 105L from the detector circuit 22L to the bias circuit 18 is short. As a result, the response speed to load variations is fast, thereby suppressing degradation in the quality of high-frequency output signals.

The first embodiment and the first to twelfth modifications have been described above, in which the power amplifier circuit 1 includes the drive-level detector circuit 26 and the detector circuit 22 operates in a feedback manner in response to the signal S1 outputted from the drive-level detector circuit 26. However, the present disclosure is not limited thereto. In the present disclosure, the detector circuit 22 may operate in a feedback manner based on the signal S1 outputted from the bias circuit 15. Hereinafter, a second embodiment will be described, in which the detector circuit 22 operates in a feedback manner based on the signal S1 outputted from the bias circuit 15.

### Second Embodiment

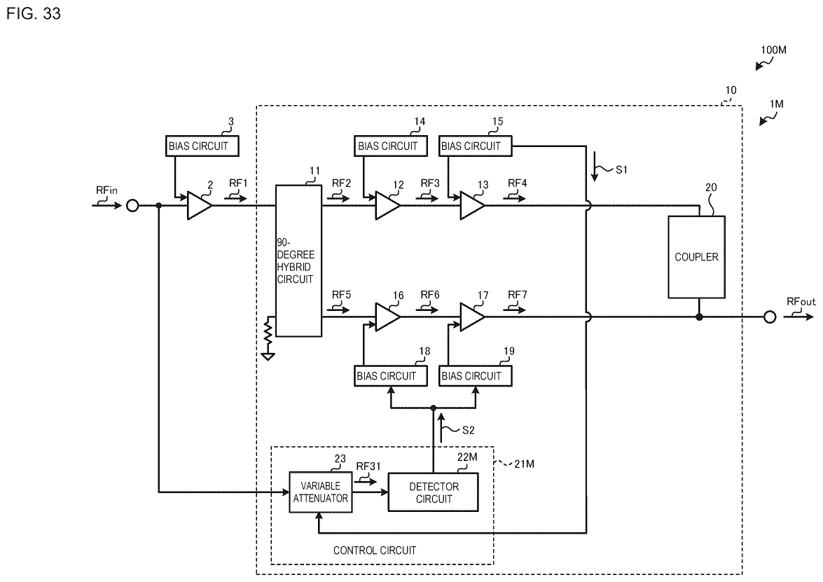

FIG. 33 illustrates a configuration of a power amplifier circuit of the second embodiment. As illustrated in FIG. 33, a power amplification device 100M of the second embodiment includes a power amplifier circuit 1M. The second embodiment differs from the first embodiment in that a Doherty amplifier 10M of the power amplifier circuit 1M includes a variable attenuator 23 instead of the drive-level detector circuit 26.

The variable attenuator 23 receives the high-frequency signal RFin and the signal S1, which indicates the drive level of the carrier amplifier 13. The variable attenuator 23 may receive the high-frequency signal RF1 instead of the high-frequency signal RFin.

The variable attenuator 23 attenuates the high-frequency signal RFin based on the signal S1 and outputs the resulting signal as a high-frequency signal RF31 to a detector circuit 22M. The detector circuit 22M outputs the signal S2 to the bias circuits 18 and 19 based on the high-frequency signal RF31.

In the second embodiment, the bias point of the detector circuit 22M is fixed. The amount of attenuation of the variable attenuator 23, which is provided upstream of the detector circuit 22M, is changed based on the signal S1. A control circuit 21M can thereby output the signal S2 based on the drive level of the carrier amplifier 13.

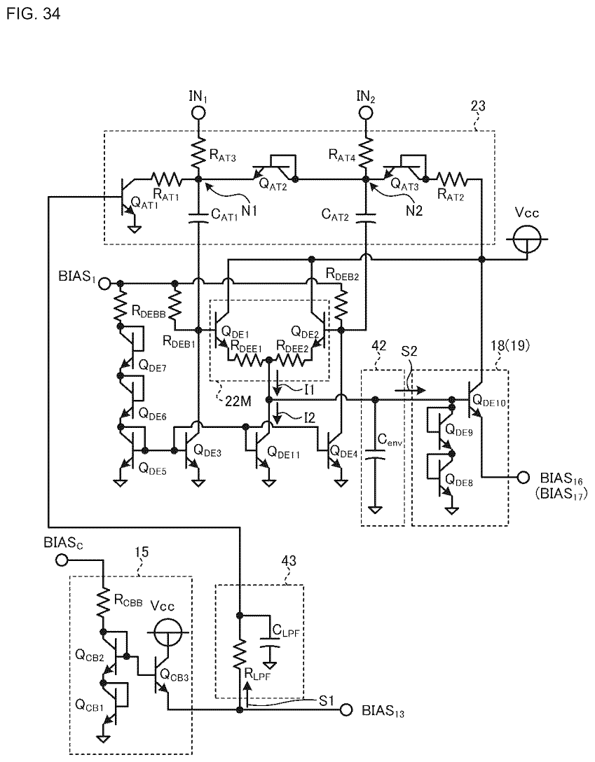

FIG. 34 illustrates a configuration of the detector circuit of the power amplifier circuit of the second embodiment. As illustrated in FIG. 34, the base of the transistor Q_{DE11} is electrically coupled to the collector and base of the transistor Q_{DE5}. In the second embodiment, therefore, the collector current I2 is fixed.

The variable attenuator 23 includes resistors R_{AT1}, R_{AT2}, R_{AT3}, and R_{AT4} and transistors Q_{AT1}, Q_{AT2}, Q_{AT3}, and capacitors C_{AT1} and C_{AT2}.

One end of the resistor R_{AT2} is electrically coupled to the power supply potential Vcc. The other end of the resistor R_{AT2} is electrically coupled to the collector and base of the transistor Q_{AT3}. That is, the transistor Q_{AT3} is diode-coupled. The emitter of the transistor Q_{AT3} is electrically coupled to a node N2.

The collector and base of the transistor Q_{AT2} are electrically coupled to the node N2. That is, the transistor Q_{AT2} is diode-coupled. The emitter of the transistor Q_{AT2} is electrically coupled to a node N1.

One end of the resistor R_{AT1} is electrically coupled to the node N1. The other end of the resistor R_{AT1} is electrically coupled to the collector of the transistor Q_{AT1}. The emitter of the transistor Q_{AT1} is electrically coupled to the reference potential. The base of the transistor Q_{AT1} receives the signal S1 that has been low-pass filtered by the low pass filter 43.

One end of the resistor R_{AT3} receives the high-frequency signal IN₁. The other end of the resistor R_{AT3} is electrically coupled to the node N1. One end of the capacitor C_{AT1} is electrically coupled to the node N1. The other end of the capacitor C_{AT1} is electrically coupled to the base of the transistor Q_{DE1}.

One end of the resistor R_{AT4} receives the high-frequency signal IN₂. The other end of the resistor R_{AT4} is electrically coupled to the node N2. One end of the capacitor C_{AT2} is electrically coupled to the node N2. The other end of the capacitor C_{AT2} is electrically coupled to the base of the transistor Q_{DE2}.

The variable attenuator 23 is an attenuator operating based on the principle that the equivalent resistance of the transistor Q_{AT1} decreases as the current flowing through the transistor Q_{AT1} increases.

When the drive level of the carrier amplifier 13 is relatively low, a relatively high voltage is applied to the base of the transistor Q_{AT1}, which serves as a control terminal of the variable attenuator 23. In this process, a large collector current flows through the transistor Q_{AT1}, and a large current also flows through the transistors Q_{AT2} and Q_{AT3}. Therefore, the equivalent resistances of the transistors Q_{AT1}, Q_{AT2}, and Q_{AT3} are reduced, and the nodes N1 and N2, to which the high-frequency signals IN₁ and IN₂ are transmitted, are nearly short-circuited. As a result, the variable attenuator 23 does not allow the high-frequency signals IN₁ and IN₂ to pass.

On the other hand, when the drive level of the carrier amplifier 13 is relatively high, no current flows through the transistors Q_{AT1}, Q_{AT2}, and Q_{AT3}. As a result, the variable attenuator 23 allows the high-frequency signals IN₁ and IN₂ to pass. Since the detector circuit 22M is provided downstream of the variable attenuator 23, the detector circuit 22M can output the signal S2 based on the drive level of the carrier amplifier 13.

The variable attenuator 23 substantially only needs to have controllable bandpass characteristics (attenuation characteristics) and ensure minimal delay in the input/output characteristics of the high-frequency signals IN₁ and IN₂. Therefore, the variable attenuator 23 can be implemented using various configurations, such as a variable gain amplifier.

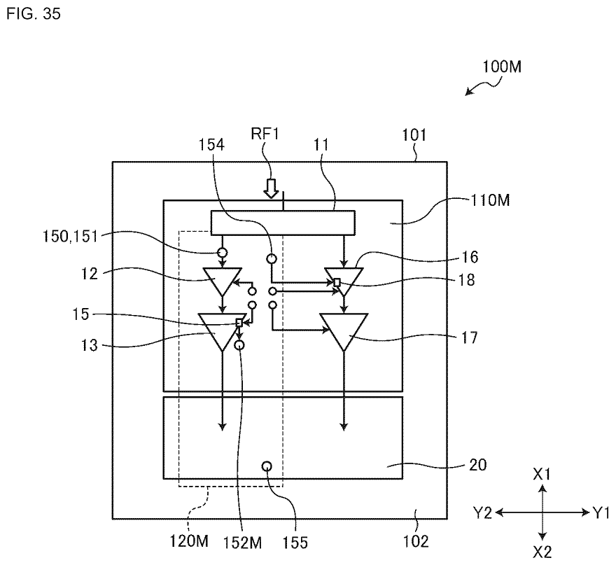

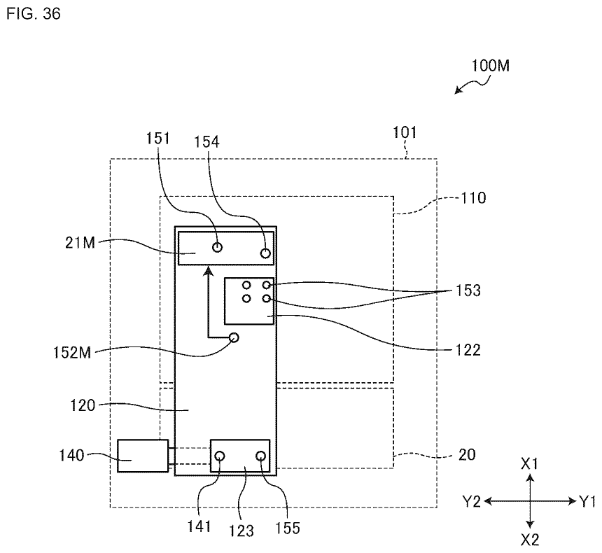

FIG. 35 is a plan view of a power amplification device of the second embodiment. FIG. 36 is a view of a second integrated circuit of the second embodiment when viewed from the substrate. Next, the layout of the power amplification device 100M will be described. The power amplification device 100M includes the substrate 101, a first integrated circuit 110M, a second integrated circuit 120M, the coupler 20, and the antenna 140. The second embodiment is the same as the first embodiment in that the first integrated circuit 110M and the coupler 20 are provided on the first surface 102 and the second integrated circuit 120 and the antenna 140 are provided on the second surface 103 (see FIG. 6). The substrate 101, the coupler 20, and the antenna 140 are already described in the first embodiment, and the description thereof is omitted.

The first integrated circuit 110M is a heterojunction bipolar transistor (HBT) circuit. The first integrated circuit 110M includes the splitter 11, the carrier amplifier 12, the carrier amplifier 13, the bias circuit 14 (see FIG. 1), the bias circuit 15, the peak amplifier 16, the peak amplifier 17, the bias circuit 18, and the bias circuit 19 (see FIG. 1). The second integrated circuit 120M includes the control circuit 21M, the PAC 122, and the switch 123. The control circuit 21M includes the detector circuit 22M and the variable attenuator 23.

A second through via 152M of the through vias 150 is disposed between the carrier amplifier 13 and the peak amplifier 17. The second through via 152M is disposed close to the carrier amplifier 13 and in proximity to the bias circuit 15 for the carrier amplifier 13. The signal S1 outputted from the bias circuit 15 is transmitted to the second surface 103 side via the second through via 152M and then transmitted to the control circuit 21M, which is included in the second integrated circuit 120M.

According to the power amplification device 100M of the second embodiment, the control circuit 21M (the detector circuit 22M) is not provided on the same surface (the first surface 102) as the carrier amplifier 13 and the peak amplifier 17. Therefore, the control circuit 21M (the detector circuit 22M) is less susceptible to heat generated by the carrier amplifier 13 and the peak amplifier 17. Furthermore, the control circuit 21M (the detector circuit 22M) is located close to the end of the second integrated circuit 120 in the first longitudinal direction X1 and does not overlap the carrier amplifier 13 and the peak amplifier 17 in plan view. From this aspect as well, the detector circuit 22M is less susceptible to heat generated by the carrier amplifier 13 and the peak amplifier 17. As a result, degradation in the characteristics of the detector circuit 22M is suppressed.

The second embodiment has been described above. In the present disclosure, differential amplifiers (the first differential amplifiers 13a and 17a and the second differential amplifiers 13b and 17b) may be used instead of the carrier amplifier 13 and the peak amplifier 17 of the second embodiment.

### Third Embodiment

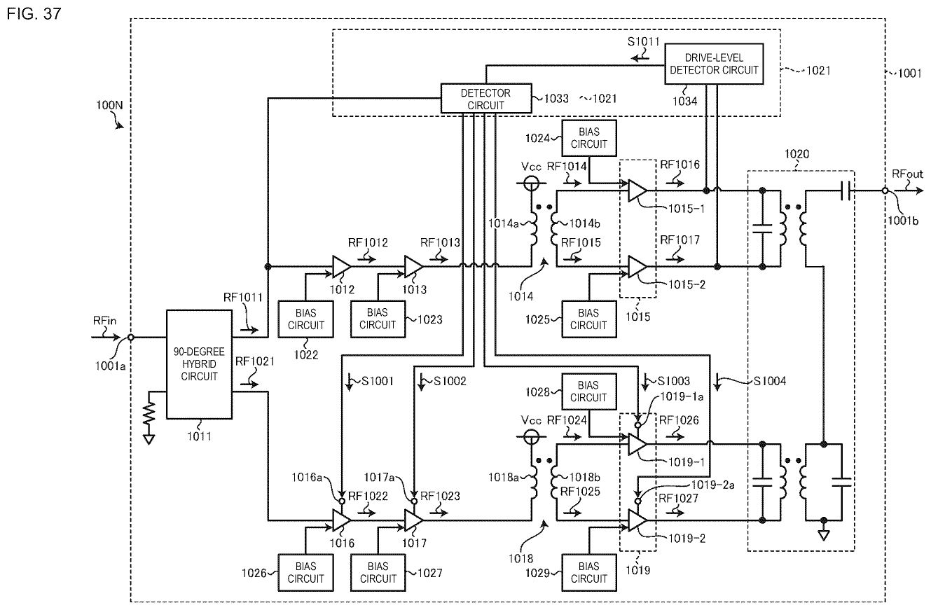

In a power amplification device according to a third embodiment, a control circuit is coupled to a peak amplifier. FIG. 37 illustrates a circuit configuration of the power amplification device according to the third embodiment. A Doherty amplifier 1001 included in a power amplification device 100N according to the third embodiment amplifies the high-frequency signal RFin inputted to an input terminal 1001a and outputs the high-frequency signal RFout from the output terminal 1001b.

The Doherty amplifier 1001 includes a splitter 1011, a first-stage (driver-stage) carrier amplifier 1012, a middle-stage carrier amplifier 1013, a balun 1014, a final-stage (power-stage) carrier amplifier 1015, a first-stage peak amplifier 1016, a middle-stage peak amplifier 1017, a balun 1018, a final-stage peak amplifier 1019, a coupler 1020, a control circuit 1021, a drive-level detector circuit 1034, and bias circuits 1022 to 1029. The control circuit 1021 includes a detector circuit 1033. The Doherty amplifier 1001 includes three stages, but the present disclosure is not limited thereto. The number of stages of the Doherty amplifier 1001 may be one, two, or four or more.

The splitter 1011 is a 90-degree hybrid circuit. The 90-degree hybrid circuit splits the high-frequency signal RFin inputted to the input terminal 1001a into high-frequency signals RF1011 and RF1021, which differ in phase by substantially 90°. The 90-degree hybrid circuit then outputs the high-frequency signal RF1011 to the carrier amplifiers 1012 and the detector circuit 1033 and outputs the high-frequency signal RF1021 to the peak amplifier 1016. The term “substantially 90°” includes not only a phase difference of 90° but also phase differences ranging from 45° to 135°.

The phase of the high-frequency signal RF1021 is exemplified as lagging behind that of the high-frequency signal RF1011 by 90°. The power of the high-frequency signal RF1021 is exemplified as being equal to that of the high-frequency signal RF1011.

The bias circuit 1022 provides bias to the carrier amplifier 1012. The carrier amplifier 1012 amplifies the high-frequency signal RF1011 and outputs the resulting signal as a high-frequency signal RF1012 to the carrier amplifier 1013. The bias circuit 1023 provides bias to the carrier amplifier 1013. The carrier amplifier 1013 amplifies the high-frequency signal RF1012 and outputs the resulting signal as a high-frequency signal RF1013 to one end of a first winding 1014a of the balun 1014.

The other end of the first winding 1014a of the balun 1014 is electrically coupled to the power supply potential Vcc. The balun 1014 transforms the high-frequency signal RF1013 into high-frequency signals RF1014 and RF1015, which constitute a differential signal, and outputs the high-frequency signals RF1014 and RF1015 from the respective ends of a second winding 1014b.

The bias circuit 1024 provides bias to a carrier amplifier. The carrier amplifier 1015-1 amplifies the high-frequency signal RF1014 and outputs the resulting signal as a high-frequency signal RF1016 to the coupler 1020. The bias circuit 1025 provides bias to a carrier amplifier 1015-2. The carrier amplifier 1015-2 amplifies the high-frequency signal RF1015 and outputs the resulting signal as a high-frequency signal RF1017 to the coupler 1020.

The bias circuit 1026 provides bias to the peak amplifier 1016. The peak amplifier 1016 includes an enable terminal 1016a, which is used to control an operating state (a high-frequency signal amplified state) and a non-operating state (a high-frequency signal non-amplified state). The enable terminal 1016a receives a control signal S1001 from the detector circuit 1033. The peak amplifier 1016 is switched to the operating state or the non-operating state depending on the control signal S1001. The control signal S1001 may be a voltage signal or a current signal. In the operating state, the peak amplifier 1016 amplifies the high-frequency signal RF1021 and outputs the resulting signal as a high-frequency signal RF1022 to the peak amplifier 1017. In the non-operating state, the peak amplifier 1016 does not amplify the high-frequency signal RF1021.

The other end of a first winding 1018a of the balun 1018 is electrically coupled to the power supply potential Vcc. The balun 1018 transforms the high-frequency signal RF1023 into high-frequency signals RF1024 and RF1025, which constitute a differential signal, and outputs the high-frequency signals RF1024 and RF1025 from the respective ends of a second winding 1018b.

The bias circuit 1027 provides bias to the peak amplifier 1017. The peak amplifier 1017 includes an enable terminal 1017a, which is used to control the operating state and the non-operating state. The enable terminal 1017a receives a control signal S1002 from the detector circuit 1033. The peak amplifier 1017 is switched to the operating state or the non-operating state depending on the control signal S1002. The control signal S1002 may be a voltage signal or a current signal. In the operating state, the peak amplifier 1017 amplifies the high-frequency signal RF1022 and outputs the resulting signal as a high-frequency signal RF1023 to one end of the first winding 1018a of the balun 1018. In the non-operating state, the peak amplifier 1017 does not amplify the high-frequency signal RF1022.

The bias circuit 1028 provides bias to a peak amplifier 1019-1. The peak amplifier 1019-1 includes an enable terminal 1019-1a, which is used to control the operating state and the non-operating state. The enable terminal 1019-1a receives a control signal S1003 from the detector circuit 1033. The peak amplifier 1019-1 is switched to the operating state or the non-operating state depending on the control signal S1003. The control signal S1003 may be a voltage signal or a current signal. In the operating state, the peak amplifier 1019-1 amplifies the high-frequency signal RF1024 and outputs the resulting signal as a high-frequency signal RF1026 to the coupler 1020. In the non-operating state, the peak amplifier 1019-1 does not amplify the high-frequency signal RF1024.

The bias circuit 1029 provides bias to a peak amplifier 1019-2. The peak amplifier 1019-2 includes an enable terminal 1019-2a, which is used to control the operating state and the non-operating state. The enable terminal 1019-2a receives a control signal S1004 from the detector circuit 1033. The peak amplifier 1019-2 is switched to the operating state or the non-operating state depending on the control signal S1004. The control signal S1004 may be a voltage signal or a current signal. In the operating state, the peak amplifier 1019-2 amplifies the high-frequency signal RF1025 and outputs the resulting signal as a high-frequency signal RF1027 to the coupler 1020. In the non-operating state, the peak amplifier 1019-2 does not amplify the high-frequency signal RF1025.

In the third embodiment, the carrier amplifier 1015 is a differential amplifier including the carrier amplifier 1015-1 for the first phase and the carrier amplifier 1015-2 for the second phase. In the third embodiment, the peak amplifier 1019 is a differential amplifier including the peak amplifier 1019-1 for the first phase and the peak amplifier 1019-2 for the second phase. In the third embodiment, preferably, the difference in voltage amplitude between output signals of one amplifier within the differential amplifier and the other amplifier is less than or equal to 3 dB, and the phase difference ranges from 90° to 270°.

In the third embodiment, each of the carrier amplifiers 1012 and 1013 is a single-ended amplifier, but the present disclosure is not limited thereto. The carrier amplifiers 1012 and 1013 may each be a differential amplifier. In the third embodiment, each of the peak amplifiers 1016 and 1017 is a single-ended amplifier, but the present disclosure is not limited thereto. The peak amplifiers 1016 and 1017 may each be a differential amplifier.

In the third embodiment, the carrier amplifier 1015 is a differential amplifier, but the present disclosure is not limited thereto. The carrier amplifier 1015 may be a single-ended amplifier. In the third embodiment, the peak amplifier 1019 is a differential amplifier, but the present disclosure is not limited thereto. The peak amplifier 1019 may be a single-ended amplifier.

When the peak amplifiers 1016, 1017, 1019-1, and 1019-2 are in the non-operating state, the coupler 1020 couples the high-frequency signals RF1016 and RF1017 to output the high-frequency signal RFout. When the peak amplifiers 1016, 1017, 1019-1, and 1019-2 are in the operating state, the coupler 1020 couples the high-frequency signals RF1016, RF1017, RF1026, and RF1027 to output the high-frequency signal RFout.

The drive-level detector circuit 1034 detects the drive level (operating level) of the carrier amplifier 1015 based on the high-frequency signals RF1016 and RF1017 and outputs a detection signal S1011, which indicates the drive level of the carrier amplifier 1015, to the detector circuit 1033. The detection signal S1011 may be a signal (an inverted signal) that changes complementarily to the drive level of the carrier amplifier 1015.

The detector circuit 1033, respectively, outputs the control signals S1001, S1002, S1003, and S1004 to the peak amplifiers 1016, 1017, 1019-1, and 1019-2 based on the high-frequency signal RF1011. For example, the detector circuit 1033 is exemplified as outputting the control signals S1001, S1002, S1003, and S1004 to switch the peak amplifiers 1016, 1017, 1019-1, and 1019-2 to the operating state when the amplitude of the high-frequency signal RF1011 is large. For example, the detector circuit 1033 is exemplified as outputting the control signals S1001, S1002, S1003, and S1004 to switch the peak amplifiers 1016, 1017, 1019-1, and 1019-2 to the non-operating state when the amplitude of the high-frequency signal RF1011 is small.

In the third embodiment, the detector circuit 1033 receives the high-frequency signal RF1011, but the present disclosure is not limited thereto. The detector circuit 1033 may receive the high-frequency signal RFin instead of the high-frequency signal RF1011.

When the control signals are current signals, as illustrated in FIG. 37, the detector circuit 1033 preferably outputs the separate control signals S1001 to S1004 to the peak amplifiers 1016, 1017, 1019-1, and 1019-2, respectively. When the control signals are voltage signals, the detector circuit 1033 preferably outputs a single common control signal to the peak amplifiers 1016, 1017, 1019-1, and 1019-2.

In the following, the peak amplifiers including the enable terminal will be described.

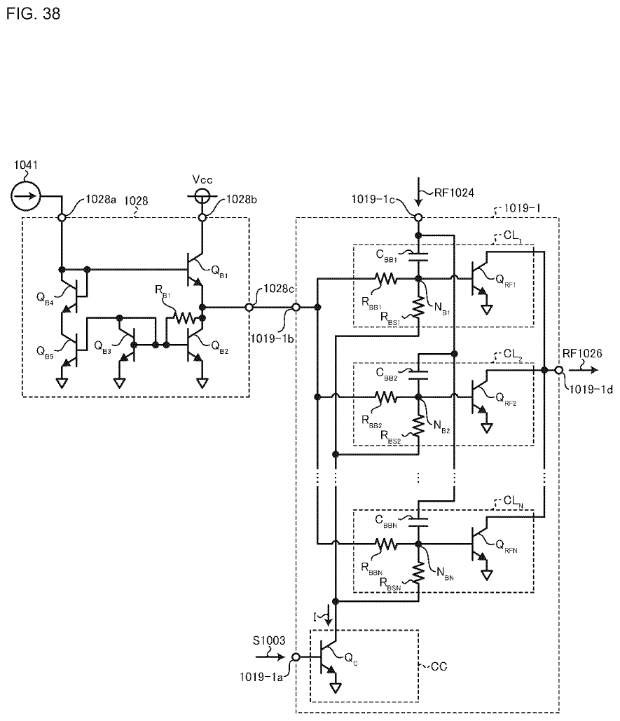

FIG. 38 illustrates a circuit configuration of the peak amplifiers according to the third embodiment. FIG. 38 illustrates the final-stage peak amplifier 1019-1 for the first phase as an example of the peak amplifiers included in the Doherty amplifier 1001. However, the other peak amplifiers can be configured in a similar manner.

A terminal 1028a of the bias circuit 1028 receives constant current from a constant-current source 1041. A terminal 1028b of the bias circuit 1028 is electrically coupled to the power supply potential Vcc.

The bias circuit 1028 includes transistors Q_{B1}, Q_{B2}, Q_{B3}, Q_{B4}, and Q_{B5} and a resistor R_{B1}.

In the third embodiment, each transistor is a bipolar transistor. However, the present disclosure is not limited thereto. The bipolar transistors are exemplified as heterojunction bipolar transistors (HBTs), but the present disclosure is not limited thereto. The transistors may be, for example, field-effect transistors (FETs). The transistors may be multi-finger transistors, in which a plurality of unit transistors are electrically coupled in parallel. Each unit transistor refers to the minimum structure that constitutes a transistor.

When each transistor is an FET, the source corresponds to the emitter of the bipolar transistor, the gate corresponds to the base, and the drain corresponds to the collector.

The collector and base of the transistor Q_{B4} are electrically coupled to the terminal 1028a. That is, the transistor Q_{B4} is diode-coupled.

The collector of the transistor Q_{B5} is electrically coupled to the emitter of the transistor Q_{B4}. The emitter of the transistor Q_{B5} is electrically coupled to the reference potential. The reference potential is exemplified as ground potential, but the present disclosure is not limited thereto.

The collector of the transistor Q_{B1} is electrically coupled to the terminal 1028b. The base of the transistor Q_{B1} is electrically coupled to the terminal 1028a and the collector and base of the transistor Q_{B4}. The emitter of the transistor Q_{B1} is electrically coupled to a terminal 1028c of the bias circuit 1028. The transistor Q_{B1} is a transistor that outputs bias voltage or bias current.

The collector of the transistor Q_{B2} is electrically coupled to the emitter of the transistor Q_{B1} and the terminal 28c. The emitter of the transistor Q_{B2} is electrically coupled to the reference potential.

One end of the resistor R_{B1} is electrically coupled to the emitter of the transistor Q_{B1}, the terminal 28c, and the collector of the transistor Q_{B2}. The other end of the resistor R_{B1} is electrically coupled to the base of the transistor Q_{B2}.

The base and collector of the transistor Q_{B3} are electrically coupled to the base of the transistor Q_{B2}, the other end of the resistor R_{B1}, and the base of the transistor Q_{B5}.

The enable terminal 1019-1a of the peak amplifier 1019-1 receives the control signal S3 from the detector circuit 1033 (see FIG. 37). A terminal 1019-1b of the peak amplifier 1019-1 receives bias current or bias voltage from the bias circuit 1028. A terminal 1019-1c of the peak amplifier 1019-1 receives the high-frequency signal RF1024 from the balun 1018 (see FIG. 37). A terminal 1019-1d of the peak amplifier 1019-1 outputs the high-frequency signal RF1026 to the coupler 1020 (see FIG. 37).

The peak amplifier 1019-1 includes cells CL₁, CL₂, . . . , and CL_{N}. That is, the peak amplifier 1019-1 is composed of a multi-finger (multi-cell) transistor including a plurality of cells. However, the present disclosure is not limited thereto. The peak amplifier 1019-1 may be composed of a single-finger (single-cell) transistor including a single cell.

The peak amplifier 1019-1 further includes a state control circuit CC, which switches the cells CL₁, CL₂, . . . , and CL_{N} between the operating state (the high-frequency signal amplified state) and the non-operating state (the high-frequency signal non-amplified state). The state control circuit CC includes a transistor Qc.

The cell CL₁ includes a transistor Q_{RF1}, a capacitor C_{BB1}, and resistors R_{BB1} and R_{BS1}. The transistor Q_{RF1} is exemplified as the unit transistor, but the present disclosure is not limited thereto.

One end of the resistor R_{BB1} is electrically coupled to the terminal 1019-1b. That is, the resistor R_{BB1} is coupled to the transistor Q_{B1} within the bias circuit 1028 as an emitter-follower. The other end of the resistor R_{BB1} is electrically coupled to the node N_{B1}. One end of the capacitor C_{BB1} is electrically coupled to the terminal 1019-1c. The other end of the capacitor C_{BB1} is electrically coupled to the node N_{B1}. The base of the transistor Q_{RF1} is electrically coupled to the node N_{B1}. The emitter of the transistor Q_{RF1} is electrically coupled to the reference potential. The collector of the transistor Q_{RF1} is electrically coupled to the terminal 1019-1d.

The base of the transistor Q_{RF1} receives the bias current or bias voltage via the resistor R_{BB1}. The base of the transistor Q_{RF1} also receives the high-frequency signal RF1024 via the capacitor C_{BB1}. The transistor Q_{RF1} amplifies the high-frequency signal RF1024 and outputs the high-frequency signal RF1026 from the collector to the terminal 1019-1d.

One end of the resistor R_{BS1} is electrically coupled to the node N_{B1}. The other end of the resistor R_{BS1} is electrically coupled to the collector of the transistor Qc.

The cell CL₂ includes a transistor Q_{RF2}, a capacitor C_{BB2}, and resistors R_{BB2} and R_{BS2}. The transistor Q_{RF2} is exemplified as the unit transistor, but the present disclosure is not limited thereto. The connection relationship between the transistor Q_{RF2}, the capacitor C_{BB2}, the node N_{B2}, and the resistors R_{BB2} and R_{BS2} is the same as that between the transistor Q_{RF1}, the capacitor C_{BB1}, the node N_{B1}, and the resistors R_{BB1} and R_{BS1}, and the description thereof is omitted.

The cell CL_{N} includes a transistor Q_{RFN}, a capacitor C_{BBN}, and resistors R_{BBN} and R_{BSN}. The transistor Q_{RFN} is exemplified as the unit transistor, but the present disclosure is not limited thereto. The connection relationship between the transistor Q_{RFN}, the capacitor C_{BBN}, the node N_{BN}, and the resistors R_{BBN} and R_{BSN} is the same as that between the transistor Q_{RF1}, the capacitor C_{BB1}, the node N_{B1}, and the resistors R_{BB1} and R_{BS1}, and the description thereof is omitted.

The collector of the transistor Qc is electrically coupled to the other end of the resistor R_{BS1}, the other end of the resistor R_{BS2}, . . . , and the other end of the resistor R_{BSN}. The base of the transistor Qc is electrically coupled to the enable terminal 19-1a. The base of the transistor Qc receives the control signal S1003. The emitter of the transistor Qc is electrically coupled to the reference potential.

The operation of the state control circuit CC will be described.

When the control signal S1003 is high, the transistor QC is on, and current I flows from the nodes N_{B1}, N_{B2}, . . . , and N_{BN} to the collector of the transistor Qc via the resistors R_{BS1}, R_{BS2}, . . . , R_{BSN}, respectively. That is, the transistor Qc draws the current I from the nodes N_{B1}, N_{B2}, . . . , and N_{BN}.

When current is drawn from the node N_{B1}, a voltage drop occurs across the resistor R_{BB1}, through which the drawn current flows, and the voltage at the node NBI decreases. As a result, the base voltage of the transistor Q_{RF1} decreases, and the transistor Q_{RF1} is unable to amplify the high-frequency signal RF1024.

In a similar manner, when current is drawn from the node N_{B2}, a voltage drop occurs across the resistor R_{BB2}, through which the drawn current flows, and the voltage at the node N_{B2} decreases. As a result, the base voltage of the transistor Q_{RF2} decreases, and the transistor Q_{RF2} is unable to amplify the high-frequency signal RF1024.

In a similar manner, when current is drawn from the node N_{BN}, a voltage drop occurs across the resistor R_{BBN} through which the drawn current flows, and the voltage at the node N_{BN} decreases. As a result, the base voltage of the transistor Q_{RFN} decreases, and the transistor Q_{RFN} is unable to amplify the high-frequency signal RF1024.

That is, when the control signal S1003 goes high, the peak amplifier 1019-1 switches to the non-operating state (the high-frequency signal non-amplified state).

When the control signal S1003 is low, the transistor Qc is off, and the current I does not flow from the nodes N_{B1}, N_{B2}, . . . , and N_{BN} to the collector of the transistor Qc. That is, the transistor Qc does not draw the current I from the nodes N_{B1}, N_{B2}, . . . , and N_{BN}.

As a result, the base voltage of the transistor Q_{RF1} does not decrease, and the transistor Q_{RF1} is able to amplify the high-frequency signal RF1024. In a similar manner, the base voltage of the transistor Q_{RF2} does not decrease, and the transistor Q_{RF2} is able to amplify the high-frequency signal RF1024. In a similar manner, the base voltage of the transistor Q_{RFN} does not decrease, and the transistor Q_{RFN} is able to amplify the high-frequency signal RF1024.

That is, when the control signal S1003 goes low, the peak amplifier 1019-1 switches to the operating state (the high-frequency signal amplified state).

The state control circuit CC may be disposed away from the cells CL₁, CL₂, . . . , and CL_{N}. This is because the current I is less affected by temperature differences. Typically, the detector circuit 1033, which is configured to generate the control signal S1003, is disposed away from the peak amplifiers 1019-1 and 1019-2 as the final-stage amplifier. Therefore, a temperature difference often occurs between the detector circuit 1033 and the peak amplifiers 1019-1 and 1019-2, which are required to output high power and tend to become hot. As a result, the threshold voltage of transistors arranged near the peak amplifiers 1019-1 and 1019-2 tend to be lower than that of transistors arranged near the detector circuit 1033.

Here, if the state control circuit CC is disposed near the peak amplifiers 1019-1 and 1019-2, the increased temperature around the peak amplifiers 1019-1 and 1019-2 causes a decrease in threshold voltage of the transistor Qc, which is included in the state control circuit CC. That is, in the configuration where the state control circuit CC is disposed near the cells CL₁, CL₂, . . . , and CL_{N}, even when the control signal S1003 generated by the detector circuit 1033 is low, the state control circuit CC can mistakenly recognize that “the control signal S1003 is high”. By contrast, in the configuration where the state control circuit CC is disposed away from the cells CL₁, CL₂, . . . , and CL_{N}, the decrease in threshold voltage of the transistor Qc, which is included in the state control circuit CC, can be reduced. This facilitates preventing the misrecognition of the control signal S1003 by the state control circuit CC. For example, the state control circuit CC may be disposed within the control circuit 1021 (see FIG. 37). In this case, the current I can be considered to correspond to the control signal S1003.

The resistor R_{BB1} is preferably disposed near the transistor Q_{RF1}. This is because voltage tends to be affected by parasitic capacitance. If the resistor R_{BB1} is disposed away from the transistor Q_{RF1}, the influence of the parasitic capacitance delays the transmission of the voltage drop across the resistor R_{BB1} to the base of the transistor Q_{RF1}. This causes a delay in switching between the operating state and the non-operating state of the transistor Q_{RF1}. In order to accelerate the switching of the transistor Q_{RF1}, it is preferable that the resistor R_{BB1} is disposed near the transistor Q_{RF1}. The same applies to the other cells.

For example, if the bias circuit 1028 controls the operating state (the high-frequency signal amplified state) and the non-operating state (the high-frequency signal non-amplified state) of the peak amplifier 1019-1 by changing the bias current or bias voltage, like the technique described in U.S. Patent Application Publication No. 2016/0241209, the switching is delayed. This is because it takes time to change DC current (the bias current) or DC voltage (the bias voltage).

On the other hand, the operating state and non-operating state of the peak amplifier 1019-1 according to the third embodiment can be controlled by inputting the control signal S1003, which can be high or low level, to the enable terminal 1019-1a. Therefore, the bias circuit 1028 does not need to change the bias current or bias voltage. As a result, the peak amplifier 1019-1 according to the third embodiment can quickly switch between the operating state and the non-operating state.

In the peak amplifier 1019-1 according to the third embodiment, the operating state and the non-operating state of the peak amplifier 1019-1 can be controlled by the state control circuit CC drawing the current I from the nodes N_{B1}, N_{B2}, . . . , and N_{BN}. Since the operating state and the non-operating state of the peak amplifier 1019-1 according to the third embodiment can be controlled by drawing the current I in this manner, the peak amplifier 1019-1 can switch more quickly than when the operating state and the non-operating state are controlled based on voltage.

As illustrated in FIGS. 6 to 8, the power amplification device 100N of the third embodiment includes the substrate 101, the first integrated circuit 110, the second integrated circuit 120, the coupler 1020 (see the coupler 20 in FIG. 6), and the antenna 140.

As illustrated in FIG. 7, the first integrated circuit 110 includes the splitter 1011 (see the splitter 11 in FIG. 7), the first-stage carrier amplifier 1012 (see the carrier amplifier 12 in FIG. 7), the final-stage carrier amplifiers 1015-1 and 1015-2 (see the carrier amplifier 13 in FIG. 7), the bias circuit 1022 (not illustrated in FIG. 7, see the bias circuit 14 in FIG. 1), the bias circuits 1024 and 1025 (not illustrated in FIG. 7, see the bias circuit 15 in FIG. 1), the first-stage peak amplifier 1016 (see the peak amplifier 16 in FIG. 7), the final-stage peak amplifiers 1019-1 and 1019-2 (see the peak amplifier 17 in FIG. 7), the bias circuit 1026 (see the bias circuit 18 in FIG. 7), the bias circuits 1028 and 1029 (not illustrated in FIG. 7, see the bias circuit 19 in FIG. 1), and the drive-level detector circuit 1034 (see the drive-level detector circuit 26 in FIG. 7).

As illustrated in FIG. 8, the second integrated circuit 120 includes the detector circuit 1033 (see the detector circuit 22 in FIG. 8), the PAC 122, and the switch 123.

As described above, the power amplification device 100N of the third embodiment has the same configuration and may have the same layout as the power amplification device 100 of the first embodiment. As in the first embodiment, the detector circuit 1033 is less susceptible to heat generated by the final-stage carrier amplifiers 1015-1 and 1015-2 and the final-stage peak amplifiers 1019-1 and 1019-2. As a result, degradation in the characteristics of the detector circuit 22 is suppressed. In the example described in the third embodiment, the power amplification device 100N of the third embodiment is applied to the layout of the first embodiment. However, in the present disclosure, the layout illustrated in the first to twelfth modifications may be applied.

### Fourth Embodiment

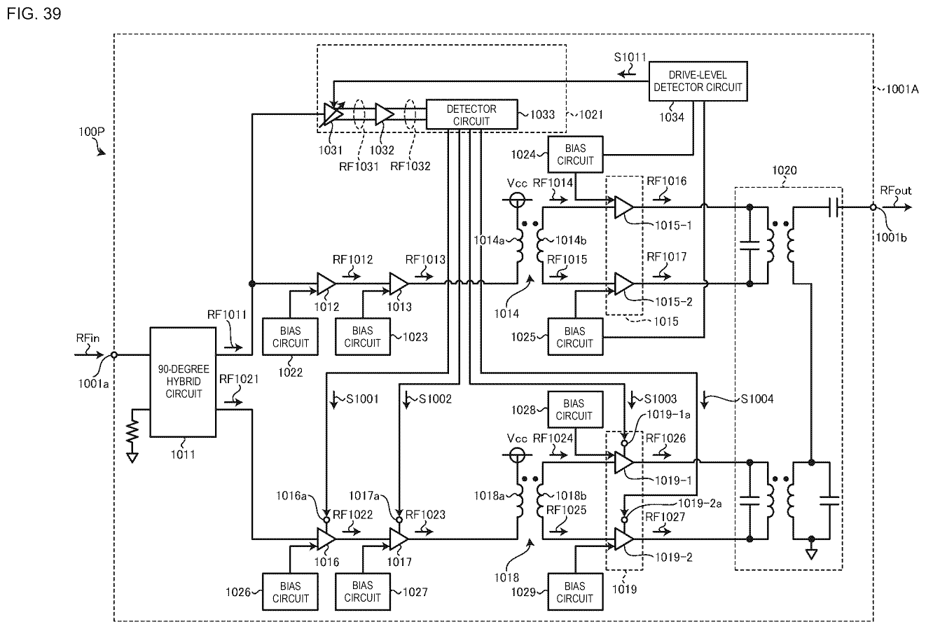

FIG. 39 illustrates a circuit configuration of a power amplification device according to a fourth embodiment. The fourth embodiment differs from the third embodiment in that the drive-level detector circuit 1034 outputs the detection signal S1011 based on high-frequency signals outputted by the bias circuits 1024 and 1025. In the fourth embodiment, the control circuit 1021 includes a variable attenuator 1031, an attenuator 1032, and the detector circuit 1033.

In the fourth embodiment, the splitter 1011 outputs the high-frequency signal RF1011 to the carrier amplifier 1012 and the variable attenuator 1031 and outputs the high-frequency signal RF1021 to the peak amplifier 1016.

The drive-level detector circuit 1034 detects the drive level (the operating level) of the carrier amplifier 1015 based on the high-frequency signals outputted by the bias circuits 1024 and 1025. The drive-level detector circuit 1034 outputs the detection signal S1011 indicating the drive level of the carrier amplifier 1015 to the variable attenuator 1031.

The variable attenuator 1031 receives the high-frequency signal RF1011 and the detection signal S1011. The variable attenuator 1031 may receive the high-frequency signal RFin instead of the high-frequency signal RF1011.

The variable attenuator 1031 attenuates and transforms the high-frequency signal RF1011 into a differential signal based on the detection signal S1011 and outputs the resulting signal as a differential high-frequency signal RF1031 to the attenuator 1032. For example, when the detection signal S1011 indicates that the carrier amplifier 1015 is close to saturation, the variable attenuator 1031 is exemplified as outputting the high-frequency signal RF1031 without significantly attenuating the high-frequency signal RF1011. Furthermore, for example, when the detection signal S1011 indicates that the carrier amplifier 1015 is not close to saturation, the variable attenuator 1031 is exemplified as significantly attenuating the high-frequency signal RF1011 to output the high-frequency signal RF1031.

In the fourth embodiment, the variable attenuator 1031 outputs the differential high-frequency signal RF1031. However, the present disclosure is not limited thereto. The variable attenuator 1031 may output a single-ended high-frequency signal. The variable attenuator 1031 may be a variable gain amplifier. In this case, the variable gain amplifier may be controlled based on the amount of amplification (gain), instead of the amount of attenuation.

The attenuator 1032 attenuates the differential high-frequency signal RF1031 and outputs a differential high-frequency signal RF1032 to the detector circuit 1033.

In the fourth embodiment, the attenuator 1032 outputs the differential high-frequency signal RF1032. However, the present disclosure is not limited thereto. The attenuator 1032 may output a single-ended high-frequency signal. The attenuator 1032 may be eliminated if the variable attenuator 1031 provides sufficient attenuation.

The detector circuit 1033, respectively, outputs the control signals S1001, S1002, S1003, and S1004 to the peak amplifiers 1016, 1017, 1019-1, and 1019-2 based on the high-frequency signal RF1032. For example, when the amplitude of the high-frequency signal RF1032 is large, the detector circuit 1033 is exemplified as outputting the control signals S1001, S1002, S1003, and S1004 to switch the peak amplifiers 1016, 1017, 1019-1, and 1019-2 to the operating state. Furthermore, for example, when the amplitude of the high-frequency signal RF1032 is small, the detector circuit 1033 is exemplified as outputting the control signals S1001, S1002, S1003, and S1004 to switch the peak amplifiers 1016, 1017, 1019-1, and 1019-2 to the non-operating state.

As illustrated in FIGS. 35 and 36, the power amplification device 100P of the fourth embodiment includes the substrate 101, the first integrated circuit (see the first integrated circuit 110M in FIG. 35), the second integrated circuit (see the second integrated circuit 120 in FIG. 36), the coupler 1020 (see the coupler 20 in FIG. 35), and the antenna 140.

As illustrated in FIG. 35, the first integrated circuit includes the splitter 1011 (see the splitter 11 in FIG. 35), the first-stage carrier amplifier 1012 (see the carrier amplifier 12 in FIG. 35), the final-stage carrier amplifiers 1015-1 and 1015-2 (see the carrier amplifier 13 in FIG. 35), the bias circuit 1022 (not illustrated in FIG. 36, see the bias circuit 14 in FIG. 1), the bias circuits 1024 and 1025 (see the bias circuit 15 in FIG. 35), the first-stage peak amplifier 1016 (see the peak amplifier 16 in FIG. 35), the final-stage peak amplifiers 1019-1 and 1019-2 (see the peak amplifier 17 in FIG. 35), the bias circuit 1026 (see the bias circuit 18 in FIG. 35), and the bias circuits 1028 and 1029 (not illustrated in FIG. 35, see the bias circuit 19 in FIG. 1). As illustrated in FIG. 36, the second integrated circuit includes the control circuit 1021 (see the control circuit 21M in FIG. 36). The control circuit 1021 includes the detector circuit 1033 and the variable attenuator 1031.

As described above, the power amplification device 100P of the fourth embodiment has the same configuration and may have the same layout as the power amplification device 100M of the second embodiment. That is, according to the power amplification device 100P of the fourth embodiment, the detector circuit 1033 (the control circuit 1021, see the control circuit 21M in FIG. 36) is not provided on the same surface (the first surface 102) as the final-stage carrier amplifiers 1015-1 and 1015-2 (see the carrier amplifier 13 in FIG. 35) and the final-stage peak amplifiers 1019-1 and 1019-2 (see the peak amplifier 17 in FIG. 35). As a result, the detector circuit 1033 is less susceptible to heat generated by the carrier amplifiers 1015-1 and 1015-23 and the peak amplifiers 1019-1 and 1019-2.

The present disclosure can also take the following aspects.
(1) A power amplification device according to an aspect of the present disclosure includes a substrate including a first surface and a second surface on a side opposite to the first surface; a first integrated circuit and a coupler that are provided on the first surface; and a second integrated circuit provided on the second surface. The first integrated circuit includes: a splitter; a carrier amplifier that amplifies an inputted high-frequency signal; a peak amplifier that amplifies an inputted high-frequency signal; a first bias circuit that provides bias to the carrier amplifier; and a second bias circuit that provides bias to the peak amplifier. The second integrated circuit includes a detector circuit that outputs a control signal to control bias of the peak amplifier. Also, the detector circuit varies a threshold for the control signal, based on a first high-frequency signal inputted to the first integrated circuit from an outside and a signal indicating a drive level of the carrier amplifier.
(2) The power amplification device according to (1), in which the radio-frequency signal is a signal to be inputted to the splitter or a signal to be inputted to the carrier amplifier.
(3) The power amplification device according to (1) or (2), in which the first integrated circuit includes a drive-level detector circuit that outputs the signal indicating the drive level of the carrier amplifier, based on a second high-frequency signal outputted by the carrier amplifier.
(4) The power amplification device according to (3), in which the substrate includes a through via passing through the first surface and the second surface, and the detector circuit and the drive-level detector circuit are coupled by the through via.
(5) The power amplification device according to (3) or (4), in which the carrier amplifier includes a first-stage carrier amplifier and a final-stage carrier amplifier, and the drive-level detector circuit is disposed adjacent to the final-stage carrier amplifier.
(6) The power amplification device according to (3) or (4), in which the carrier amplifier includes a first-stage carrier amplifier and a final-stage carrier amplifier, the final-stage carrier amplifier is composed of a pair of differential amplifiers, and the drive-level detector circuit is disposed between the pair of differential amplifiers.
(7) The power amplification device according to (1) or (2), in which the second integrated circuit includes a drive-level detector circuit that outputs the signal indicating the drive level of the carrier amplifier, based on a high-frequency signal outputted by the carrier amplifier.
(8) The power amplification device according to (7), in which the carrier amplifier includes a first-stage carrier amplifier and a final-stage carrier amplifier, the substrate includes a through via that passes through the first surface and the second surface and that is coupled to the drive-level detector circuit, and the through via is provided on a path from the final-stage carrier amplifier to the coupler.
(9) The power amplification device according to (8), in which the detector circuit is adjacent to the drive-level detector circuit.
(10) A power amplification device, including a substrate including a first surface and a second surface on a side opposite to the first surface; a first integrated circuit and a coupler that are provided on the first surface; and a second integrated circuit provided on the second surface. The first integrated circuit includes: a splitter; a carrier amplifier that amplifies an inputted high-frequency signal; a peak amplifier that amplifies an inputted high-frequency signal; a first bias circuit that provides bias to the carrier amplifier; and a second bias circuit that provides bias to the peak amplifier. The second integrated circuit includes a control circuit. The control circuit includes a detector circuit that outputs a control signal to control bias of the peak amplifier; and a variable attenuator that receives a first high-frequency signal inputted from an outside to the first integrated circuit and a signal outputted from the first bias circuit and that outputs to the detector circuit, a high-frequency signal obtained by attenuating the first high-frequency signal.
(11) The power amplification device according to any one of (1) to (10), in which the carrier amplifier includes a first-stage carrier amplifier and a final-stage carrier amplifier, and the peak amplifier includes a first-stage peak amplifier and a final-stage peak amplifier. Also, when viewed in a direction perpendicular to the first surface, the detector circuit is disposed between the first-stage carrier amplifier and the first-stage peak amplifier, and when viewed in the direction perpendicular to the first surface, an output terminal of the detector circuit is in proximity to the first-stage peak amplifier.
(12) The power amplification device according to any one of (1) to (11), in which the carrier amplifier includes a first-stage carrier amplifier and a final-stage carrier amplifier, and the peak amplifier includes a first-stage peak amplifier and a final-stage peak amplifier. Also, when viewed from the first-stage carrier amplifier and the first-stage peak amplifier, the detector circuit is disposed on a side opposite to the final-stage carrier amplifier and the final-stage peak amplifier.
(13) The power amplification device according to any one of (1) to (12), in which an axis along which the carrier amplifier and the peak amplifier are arranged is a transverse axis, and an axis that is parallel to the first surface and is perpendicular to the transverse axis is a longitudinal axis. Also, on the first surface, the carrier amplifier is disposed on one side of a center along the transverse axis, while the peak amplifier is disposed on another side. The second integrated circuit is shorter along the transverse axis than the first integrated circuit and is disposed only on one side of the center along the transverse axis, and in plan view, the second integrated circuit overlaps the carrier amplifier.

What is claimed is:

1. A power amplification device, comprising:
a substrate including a first surface and a second surface on a side opposite to the first surface;
a first integrated circuit and a coupler that are on the first surface; and
a second integrated circuit on the second surface, wherein
the first integrated circuit includes: a splitter; a carrier amplifier configured to amplify an inputted high-frequency signal; a peak amplifier configured to amplify an inputted high-frequency signal; a first bias circuit configured to provide bias to the carrier amplifier; and a second bias circuit configured to provide bias to the peak amplifier,
the second integrated circuit includes a detector circuit configured to output a control signal to control bias of the peak amplifier, and
the detector circuit is configured to vary a threshold for the control signal, based on a first high-frequency signal inputted to the first integrated circuit from an outside and a signal indicating a drive level of the carrier amplifier.

2. The power amplification device according to claim 1, wherein
the first high-frequency signal is a signal to be inputted to the splitter or a signal to be inputted to the carrier amplifier.

3. The power amplification device according to claim 1, wherein
the first integrated circuit includes a drive-level detector circuit configured to output the signal indicating the drive level of the carrier amplifier, based on a second high-frequency signal outputted by the carrier amplifier.

4. The power amplification device according to claim 3, wherein
the substrate includes a through via passing through the first surface and the second surface, and
the detector circuit and the drive-level detector circuit are coupled by the through via.

5. The power amplification device according to claim 3, wherein
the carrier amplifier includes a first-stage carrier amplifier and a final-stage carrier amplifier, and
the drive-level detector circuit is adjacent to the final-stage carrier amplifier.

6. The power amplification device according to claim 3, wherein
the carrier amplifier includes a first-stage carrier amplifier and a final-stage carrier amplifier,
the final-stage carrier amplifier includes a pair of differential amplifiers, and
the drive-level detector circuit is between the pair of differential amplifiers.

7. The power amplification device according to claim 1, wherein
the second integrated circuit includes a drive-level detector circuit configured to output the signal indicating the drive level of the carrier amplifier, based on a high-frequency signal outputted by the carrier amplifier.

8. The power amplification device according to claim 7, wherein
the carrier amplifier includes a first-stage carrier amplifier and a final-stage carrier amplifier,
the substrate includes a through via that passes through the first surface and the second surface and that is coupled to the drive-level detector circuit, and
the through via is on a path from the final-stage carrier amplifier to the coupler.

9. The power amplification device according to claim 8, wherein
the detector circuit is adjacent to the drive-level detector circuit.

10. A power amplification device, comprising:
a substrate including a first surface and a second surface on a side opposite to the first surface;
a first integrated circuit and a coupler that are on the first surface; and
a second integrated circuit on the second surface, wherein
the first integrated circuit includes a splitter; a carrier amplifier configured to amplify an inputted high-frequency signal; a peak amplifier configured to amplify an inputted high-frequency signal; a first bias circuit configured to provide bias to the carrier amplifier; and a second bias circuit configured to provide bias to the peak amplifier,
the second integrated circuit includes a control circuit,
the control circuit includes:
a detector circuit configured to output a control signal to control bias of the peak amplifier; and
a variable attenuator configured to receive a first high-frequency signal inputted from an outside to the first integrated circuit and a signal outputted from the first bias circuit, and output to the detector circuit, a high-frequency signal obtained by attenuating the first high-frequency signal.

11. The power amplification device according to claim 1, wherein
the carrier amplifier includes a first-stage carrier amplifier and a final-stage carrier amplifier,
the peak amplifier includes a first-stage peak amplifier and a final-stage peak amplifier,
when viewed in a direction perpendicular to the first surface, the detector circuit is between the first-stage carrier amplifier and the first-stage peak amplifier, and
when viewed in the direction perpendicular to the first surface, an output terminal of the detector circuit is in proximity to the first-stage peak amplifier.

12. The power amplification device according to claim 1, wherein
the carrier amplifier includes a first-stage carrier amplifier and a final-stage carrier amplifier,
the peak amplifier includes a first-stage peak amplifier and a final-stage peak amplifier, and
when viewed from the first-stage carrier amplifier and the first-stage peak amplifier, the detector circuit is on a side opposite to the final-stage carrier amplifier and the final-stage peak amplifier.

13. The power amplification device according to claim 1, wherein
an axis along which the carrier amplifier and the peak amplifier are arranged is a transverse axis,
an axis that is parallel to the first surface and is perpendicular to the transverse axis is a longitudinal axis,
on the first surface, the carrier amplifier is on one side of a center along the transverse axis, while the peak amplifier is on another side,
the second integrated circuit is shorter along the transverse axis than the first integrated circuit and is only on one side of the center along the transverse axis of the second surface, and
in plan view, the second integrated circuit overlaps the carrier amplifier.

14. The power amplification device according to claim 10, wherein
the carrier amplifier includes a first-stage carrier amplifier and a final-stage carrier amplifier,
the peak amplifier includes a first-stage peak amplifier and a final-stage peak amplifier,
when viewed in a direction perpendicular to the first surface, the detector circuit is between the first-stage carrier amplifier and the first-stage peak amplifier, and
when viewed in the direction perpendicular to the first surface, an output terminal of the detector circuit is in proximity to the first-stage peak amplifier.

15. The power amplification device according to claim 11, wherein
the carrier amplifier includes a first-stage carrier amplifier and a final-stage carrier amplifier,
the peak amplifier includes a first-stage peak amplifier and a final-stage peak amplifier, and
when viewed from the first-stage carrier amplifier and the first-stage peak amplifier, the detector circuit is on a side opposite to the final-stage carrier amplifier and the final-stage peak amplifier.

16. The power amplification device according to claim 12, wherein
an axis along which the carrier amplifier and the peak amplifier are arranged is a transverse axis,
an axis that is parallel to the first surface and is perpendicular to the transverse axis is a longitudinal axis,
on the first surface, the carrier amplifier is on one side of a center along the transverse axis, while the peak amplifier is on another side,
the second integrated circuit is shorter along the transverse axis than the first integrated circuit and is only on one side of the center along the transverse axis of the second surface, and
in plan view, the second integrated circuit overlaps the carrier amplifier.

17. The power amplification device according to claim 2, wherein
the first integrated circuit includes a drive-level detector circuit configured to output the signal indicating the drive level of the carrier amplifier, based on a second high-frequency signal outputted by the carrier amplifier.

18. The power amplification device according to claim 4, wherein
the carrier amplifier includes a first-stage carrier amplifier and a final-stage carrier amplifier, and
the drive-level detector circuit is adjacent to the final-stage carrier amplifier.

19. The power amplification device according to claim 4, wherein
the carrier amplifier includes a first-stage carrier amplifier and a final-stage carrier amplifier,
the final-stage carrier amplifier includes a pair of differential amplifiers, and
the drive-level detector circuit is between the pair of differential amplifiers.

20. The power amplification device according to claim 2, wherein
the second integrated circuit includes a drive-level detector circuit configured to output the signal indicating the drive level of the carrier amplifier, based on a high-frequency signal outputted by the carrier amplifier.
